(19) United States
(12) Patent Application Publication
(10) Pub. No.: US 2026/0112404 A1
(43) Pub. Date: Apr. 23, 2026

(54) CALIBRATION CIRCUIT, MEMORY, SYSTEM AND CALIBRATION METHOD

(71) Applicant: YANGTZE MEMORY TECHNOLOGIES CO., LTD., Wuhan (CN)

(72) Inventors: Mengjie LUO, Wuhan (CN); Zhefan LI, Wuhan (CN); Xiaodong MEI, Wuhan (CN); HuangPeng ZHANG, Wuhan (CN)

(21) Appl. No.: 19/354,605

(22) Filed: Oct. 9, 2025

(30) Foreign Application Priority Data
Oct. 17, 2024 (CN) 2024114508535

(51) Int. Cl. G11C 11/408

(52) U.S. Cl. CPC G11C 11/4085; G11C 2211/4061

(57) ABSTRACT

The present disclosure provides a calibration circuit, a memory, a system and a calibration method. The calibration circuit includes: a driver connected to a connection point; a multiplexing circuit configured to, in response to a first selection signal, output a connection point voltage of the connection point through a first output terminal of the multiplexing circuit and output a reference voltage through a second output terminal of the multiplexing circuit, and in response to a second selection signal, output the connection point voltage through the second output terminal of the multiplexing circuit and output the reference voltage through the first output terminal of the multiplexing circuit; a comparator, wherein a first input terminal of the comparator is connected to the first output terminal of the multiplexing circuit, and a second input terminal of the comparator is connected to the second output terminal of the multiplexing circuit.

### CROSS-REFERENCE TO RELATED APPLICATIONS

The present disclosure claims priority to Chinese Patent Application No. 2024114508535, which was filed October 17, 2024, and is hereby incorporated herein by reference in its entirety.

### TECHNICAL FIELD

The present disclosure relates to the technical field of a memory, in particular to a calibration circuit, a memory, a system and a calibration method..

### BACKGROUND

The memory is a memory member configured to store programs and various data information. With the development of the storage technology, a plurality of types of memories have been developed at present.

### SUMMARY

According to an aspect of the present disclosure, a calibration circuit is provided. The calibration circuit comprises: a driver connected to a connection point; a multiplexing circuit, wherein a first input terminal of the multiplexing circuit is connected to the connection point, a second input terminal of the multiplexing circuit is configured to receive a reference voltage , the multiplexing circuit is configured to, in response to a first selection signal, output a connection point voltage of the connection point through a first output terminal of the multiplexing circuit and output the reference voltage through a second output terminal of the multiplexing circuit, and, in response to a second selection signal, output the connection point voltage through the second output terminal of the multiplexing circuit and output the reference voltage through the first output terminal of the multiplexing circuit; a comparator, wherein a first input terminal of the comparator is connected to the first output terminal of the multiplexing circuit, and a second input terminal of the comparator is connected to the second output terminal of the multiplexing circuit; and a calibration control circuit, wherein an input terminal of the calibration control circuit is connected to an output terminal of the comparator, an output terminal of the calibration control circuit is connected to a control terminal of the driver, and the calibration control circuit is configured to calibrate the driver.

In some implementations, the multiplexing circuit comprises: a first multiplexer, wherein a first input terminal of the first multiplexer is connected to the connection point, a second input terminal of the first multiplexer is configured to receive the reference voltage, an output terminal of the first multiplexer is connected to the first input terminal of the comparator, and a control terminal of the first multiplexer is configured to receive the first selection signal or the second selection signal; and a second multiplexer, wherein a first input terminal of the second multiplexer is connected to the connection point, a second input terminal of the second multiplexer is configured to receive the reference voltage, an output terminal of the second multiplexer is connected to the second input terminal of the comparator, and a control terminal of the second multiplexer is configured to receive the first selection signal or the second selection signal.

In some implementations, the first multiplexer comprises: a first transistor, wherein a first terminal of the first transistor is configured to receive the connection point voltage, a second terminal of the first transistor serves as the output terminal of the first multiplexer, and a control terminal of the first transistor is configured to receive the first selection signal or the second selection signal; and a second transistor, wherein a first terminal of the second transistor is configured to receive the reference voltage, a second terminal of the second transistor is connected to the second terminal of the first transistor, and a control terminal of the second transistor is connected to the control terminal of the first transistor, wherein a conductivity type of the second transistor is opposite to a conductivity type of the first transistor.

In some implementations, the second multiplexer comprises: a third transistor, wherein a first terminal of the third transistor is connected to the first terminal of the first transistor, a second terminal of the third transistor serves as the output terminal of the second multiplexer, and a control terminal of the third transistor is connected to the control terminal of the first transistor, wherein a conductivity type of the third transistor is opposite to the conductivity type of the first transistor; and a fourth transistor, wherein a first terminal of the fourth transistor is connected to the first terminal of the second transistor, a second terminal of the fourth transistor is connected to the second terminal of the third transistor, and a control terminal of the fourth transistor is connected to the control terminal of the first transistor, wherein a conductivity type of the fourth transistor is the same as the conductivity type of the first transistor.

In some implementations, the connection point is configured to be connected to an external resistor.

In some implementations, the calibration control circuit comprises: a binary search circuit, wherein an input terminal of the binary search circuit is connected to the output terminal of the comparator, and a first output terminal of the binary search circuit is connected to the control terminal of the driver; an adder circuit, wherein a first input terminal of the adder circuit is connected to a second output terminal of the binary search circuit, and a second input terminal of the adder circuit is connected to a third output terminal of the binary search circuit; and a first shift circuit, wherein an input terminal of the first shift circuit is connected to an output terminal of the adder circuit, and an output terminal of the first shift circuit is connected to the control terminal of the driver.

In some implementations, the calibration control circuit comprises: a binary search circuit, wherein an input terminal of the binary search circuit is connected to the output terminal of the comparator, and a first output terminal of the binary search circuit is connected to the control terminal of the driver; a subtraction circuit, wherein a first input terminal of the subtraction circuit is connected to a second output terminal of the binary search circuit, and a second input terminal of the subtraction circuit is connected to a third output terminal of the binary search circuit; a second shift circuit, wherein an input terminal of the second shift circuit is connected to an output terminal of the subtraction circuit; and an adder circuit, wherein a first input terminal of the adder circuit is connected to an output terminal of the second shift circuit, and a second input terminal of the adder circuit is connected to the third output terminal of the binary search circuit.

In some implementations, the calibration control circuit further comprises: a subtraction circuit, wherein a first input terminal of the subtraction circuit is connected to the second output terminal of the binary search circuit, and a second input terminal of the subtraction circuit is connected to the third output terminal of the binary search circuit; and a second shift circuit, wherein an input terminal of the second shift circuit is connected to an output terminal of the subtraction circuit, and an output terminal of the second shift circuit is connected to the first input terminal of the adder circuit.

In some implementations, the calibration control circuit further comprises: a third multiplexer arranged between the second shift circuit and the adder circuit and between the binary search circuit and the adder circuit, wherein a first input terminal of the third multiplexer is connected to the second output terminal of the binary search circuit, a second input terminal of the third multiplexer is connected to the output terminal of the second shift circuit, an output terminal of the third multiplexer is connected to the first input terminal of the adder circuit, and a control terminal of the third multiplexer is configured to receive a first control signal or a second control signal.

In some implementations, the calibration control circuit further comprises: a fourth multiplexer arranged between the adder circuit and the first shift circuit, wherein an input terminal of the fourth multiplexer is connected to the output terminal of the adder circuit, a first output terminal of the fourth multiplexer is connected to the control terminal of the driver, a second output terminal of the fourth multiplexer is connected to the input terminal of the first shift circuit, and a control terminal of the fourth multiplexer is configured to receive the first control signal or the second control signal.

In some implementations, the calibration control circuit further comprises: a fourth multiplexer, wherein a first input terminal of the fourth multiplexer is connected to the output terminal of the adder circuit, a second input terminal of the fourth multiplexer is connected to the output terminal of the first shift circuit, an output terminal of the fourth multiplexer is connected to the control terminal of the driver, and a control terminal of the fourth multiplexer is configured to receive the first control signal or the second control signal.

In some implementations, the calibration control circuit further comprises: a state machine circuit, wherein a first input terminal of the state machine circuit is configured to receive an on command, a first output terminal of the state machine circuit is configured to output the first selection signal or the second selection signal, and a second output terminal of the state machine circuit is configured to output the first control signal or the second control signal.

In some implementations, a second input terminal of the state machine circuit is configured to receive a temperature change signal.

In some implementations, the calibration control circuit further comprises: a first latch arranged between the binary search circuit and the third multiplexer and between the binary search circuit and the subtraction circuit, wherein an input terminal of the first latch is connected to the second output terminal of the binary search circuit, and an output terminal of the first latch is connected to the first input terminal of the third multiplexer and the first input terminal of the subtraction circuit; and a second latch arranged between the binary search circuit and the adder circuit and between the binary search circuit and the subtraction circuit, wherein an input terminal of the second latch is connected to the third output terminal of the binary search circuit, and an output terminal of the second latch is connected to the second input terminal of the adder circuit and the second input terminal of the subtraction circuit.

In some implementations, the calibration control circuit further comprises: a third latch arranged between the second shift circuit and the third multiplexer, wherein an input terminal of the third latch is connected to the output terminal of the second shift circuit, and an output terminal of the third latch is connected to the second input terminal of the third multiplexer.

In some implementations, the driver is a pull-down driver or a pull-up driver.

According to another aspect of the present disclosure, a memory is provided. The memory comprises: a memory cell array; and

a peripheral circuit comprising: a word line driver coupled to the memory cell array; a page buffer coupled to the memory cell array; a control logic circuit coupled to the word line driver and the page buffer; and an interface circuit coupled to the control logic circuit, wherein the interface circuit comprises the calibration circuit described previously.

According to another aspect of the present disclosure, a system is provided. The system comprises: the memory described previously; and a controller coupled to the memory.

According to another aspect of the present disclosure, a calibration method is provided. The calibration method comprises: transmitting a connection point voltage of a connection point connected to a driver to a first input terminal of a comparator and transmitting a reference voltage to a second input terminal of the comparator by using a multiplexing circuit; outputting a first comparison result between the connection point voltage and the reference voltage by using the comparator; obtaining a first resistance code based on the first comparison result by using a calibration control circuit; transmitting the connection point voltage to the second input terminal of the comparator and transmitting the reference voltage to the first input terminal of the comparator by using the multiplexing circuit; outputting a second comparison result between the connection point voltage and the reference voltage by using the comparator; obtaining a second resistance code based on the second comparison result by using the calibration control circuit; and calibrating the driver based on the first resistance code and the second resistance code by using the calibration control circuit.

In some implementations, the obtaining of the first resistance code based on the first comparison result by using the calibration control circuit comprises: cyclically outputting the first resistance code based on the first comparison result to adjust a resistance value of the driver until a first loop exit condition is met to obtain the first resistance code meeting the first loop exit condition; the obtaining of the second resistance code based on the second comparison result by using the calibration control circuit comprises: cyclically outputting the second resistance code based on the second comparison result to adjust the resistance value of the driver until a second loop exit condition is met to obtain the second resistance code meeting the second loop exit condition; and the calibrating of the driver based on the first resistance code and the second resistance code by using the calibration control circuit comprises: calibrating the driver based on the first resistance code meeting the first loop exit condition and the second resistance code meeting the second loop exit condition.

In some implementations, the calibrating of the driver based on the first resistance code and the second resistance code by using the calibration control circuit comprises: calculating an adjustment code based on the first resistance code and the second resistance code, wherein the adjustment code is half of a sum of the first resistance code and the second resistance code; and calibrating the driver based on the adjustment code.

In some implementations, the calibrating of the driver based on the first resistance code and the second resistance code by using the calibration control circuit comprises: calculating an offset code based on the first resistance code and the second resistance code, wherein the offset code is half of a difference between the first resistance code and the second resistance code; calculating an adjustment code based on the first resistance code or the second resistance code and based on the offset code; and calibrating the driver based on the adjustment code.

In some implementations, the cyclically outputting of the first resistance code based on the first comparison result comprises: by way of binary search, cyclically outputting the first resistance code based on the first comparison result to adjust the resistance value of the driver; and the cyclically outputting of the second resistance code based on the second comparison result comprises: by way of binary search, cyclically outputting the second resistance code based on the second comparison result to adjust the resistance value of the driver.

In some implementations, the first loop exit condition comprises a first predetermined number of cycle periods; and the second loop exit condition comprises a second predetermined number of cycle periods.

In some implementations, the first loop exit condition is the same as the second loop exit condition.

In some implementations, the calibration method further comprises: reobtaining the first resistance code and the second resistance code in response to a change amplitude of a temperature of a memory within a predetermined time being greater than or equal to an amplitude threshold; calculating the adjustment code based on the first resistance code and the second resistance code which are reobtained, wherein the adjustment code is half of a sum of the first resistance code and the second resistance code; and recalibrating the driver based on the adjustment code.

In some implementations, the calibration method further comprises: reobtaining the first resistance code or the second resistance code in response to a change amplitude of a temperature of a memory within a predetermined time being less than an amplitude threshold; calculating the adjustment code based on the first resistance code or the second resistance code which is reobtained and based on the offset code; and recalibrating the driver based on the adjustment code.

In the above-described calibration circuit, the connection point voltage and the reference voltage are transmitted to the comparator through the multiplexing circuit in two different states so that the comparator obtains two comparison results, and further the calibration control circuit calibrates the driver, which can improve the accuracy of ZQ calibration.

Other features and advantages of the present disclosure will become explicit from the following detailed description of exemplary implementations of the present disclosure in conjunction with the accompanying drawings.

### BRIEF DESCRIPTION OF THE DRAWINGS

The accompanying drawings which constitute part of this specification, describe the implementations of the present disclosure, and together with this specification, serve to explain the principles of the present disclosure.

The present disclosure may be more explicitly understood from the following detailed description in conjunction with the accompanying drawings, in which:

FIG. 1 is a circuit connection view schematically showing a calibration circuit according to some implementations of the present disclosure;

FIG. 2 is a circuit connection view schematically showing a calibration circuit according to some implementations of the present disclosure when a multiplexing circuit is in one state;

FIG. 3 is a circuit connection view schematically showing a calibration circuit according to some implementations of the present disclosure when a multiplexing circuit is in another state;

FIG. 4 is a circuit connection view schematically showing a calibration circuit according to other implementations of the present disclosure;

FIG. 5 is a circuit connection view schematically showing a multiplexing circuit according to some implementations of the present disclosure;

FIG. 6 is a circuit connection view schematically showing a calibration circuit according to other implementations of the present disclosure;

FIG. 7 is a circuit connection view schematically showing a calibration circuit according to other implementations of the present disclosure;

FIG. 8 is a circuit connection view schematically showing a calibration circuit according to other implementations of the present disclosure;

FIG. 9 is a circuit connection view schematically showing a calibration circuit according to other implementations of the present disclosure;

FIG. 10 is a circuit connection view schematically showing a calibration circuit according to other implementations of the present disclosure;

FIG. 11 is a circuit connection view schematically showing a calibration circuit according to other implementations of the present disclosure;

FIG. 12 is a circuit connection view schematically showing a calibration circuit according to other implementations of the present disclosure;

FIGS. 13A and 13B (collectively referred to herein as FIG. 13) are a circuit connection view schematically showing a calibration circuit according to other implementations of the present disclosure;

FIGS. 14A and 14B (collectively referred to herein as FIG. 14) are a circuit connection view schematically showing a calibration circuit according to other implementations of the present disclosure;

FIG. 15 is a schematic view showing an operation principle of a calibration circuit according to some implementations of the present disclosure;

FIG. 16 is a schematic view showing the operation principles of a calibration circuit according to other implementations of the present disclosure;

FIG. 17 is a schematic view showing an operation principle of a calibration circuit according to other implementations of the present disclosure;

FIG. 18 is a schematic view schematically showing a binary search used by a calibration circuit according to some implementations of the present disclosure;

FIG. 19 is a flowchart showing a calibration method according to some implementations of the present disclosure;

FIG. 20 is a schematic structural view showing a memory according to some implementations of the present disclosure;

FIG. 21 is a schematic structural view showing a system according to some implementations of the present disclosure.

It should be understood that the dimensions of various parts shown in the accompanying drawings are not drawn according to actual proportional relations. In addition, the same or similar components are denoted by the same or similar reference signs.

### DETAILED DESCRIPTION

Various exemplary implementations of the present disclosure will now be described in detail in conjunction with the accompanying drawings. The description of the exemplary implementations is merely illustrative and is in no way intended as a limitation to the present disclosure, its application or use. The present disclosure may be implemented in many different forms, which are not limited to the implementations described herein. These implementations are provided to make the present disclosure thorough and complete, and fully convey the scope of the present disclosure to those skilled in the art. It should be noticed that: relative arrangement of components and steps, material composition, numerical expressions, and numerical values set forth in these implementations, unless specifically stated otherwise, should be explained as merely illustrative, and not as a limitation.

The use of the terms “first”, “second” and similar words in the present disclosure do not denote any order, quantity or importance, but are merely used to distinguish between different parts. A word such as "comprise", " include" or a similar word means that the element before the word covers the element(s) listed after the word without excluding the possibility of also covering other elements. The terms “up”, “down”, “left”, “right”, or the like are used only to represent a relative positional relationship, and the relative positional relationship may also be changed correspondingly if the absolute position of the described object changes.

In the present disclosure, when it is described that a particular device is located between the first device and the second device, there may be an intermediate device between the particular device and the first device or the second device, and alternatively, there may be no intermediate device. When it is described that a particular device is connected to other devices, the particular device may be directly connected to said other devices without an intermediate device, and alternatively, may not be directly connected to said other devices but with an intermediate device.

All the terms (comprising technical and scientific terms) used in the present disclosure have the same meanings as understood by those skilled in the art of the present disclosure unless otherwise defined. It should also be understood that terms as defined in general dictionaries, unless explicitly defined herein, should be interpreted as having meanings that are consistent with their meanings in the context of the relevant art, and not to be interpreted in an idealized or extremely formalized sense.

Techniques, methods, and apparatus known to those of ordinary skill in the relevant art may not be discussed in detail, but where appropriate, these techniques, methods, and apparatuses should be considered as part of this specification.

In the related art, in order to reduce the signal integrity (referred to as S/I for short) of the memory, the memory (for example, the memory (for example, DRAM (Dynamic Random Access Memory)) has an on-die termination (referred to as ODT for short) impedance calibration function, which is referred to as ZQ calibration. In ZQ calibration, the impedance of the pull-down driver/pull-up driver is adjusted to be equal to an external resistance according to an output signal of the voltage comparator. To some extent, the offset of the comparator is a main error during the calibration process.

In order to reduce the offset of the comparator, various technologies are used in the related art, for example, body-driven inputs and charge pump cancellation.

The inventors of the present disclosure have found that, in the related art, methods such as body-driven inputs and charge pump cancellation are limited by a narrow offset cancellation range, an increased current and DRAM process constraints, which results in a low accuracy of ZQ calibration in the related art.

In view of this, the implementation of the present disclosure provides a calibration circuit to improve the accuracy of ZQ calibration. The calibration circuit according to some implementations of the present disclosure will be described in detail below in conjunction with the accompanying drawings.

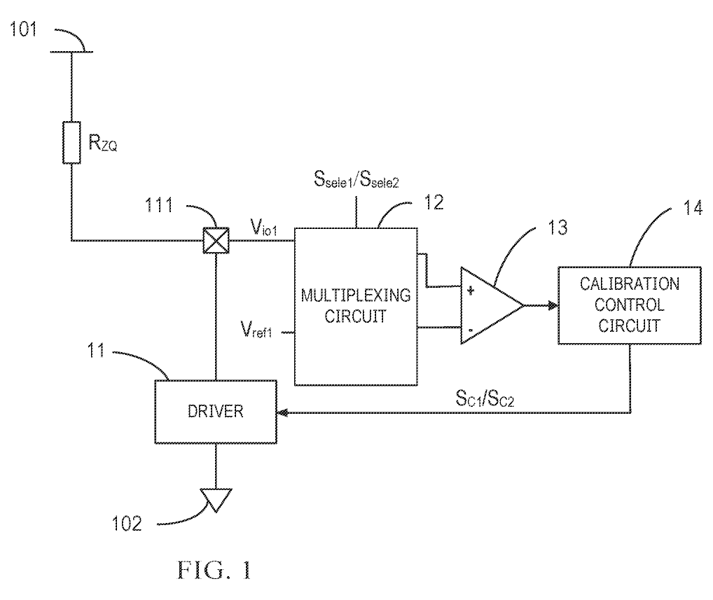

FIG. 1 is a circuit connection view schematically showing a calibration circuit according to some implementations of the present disclosure.

As shown in FIG. 1, the calibration circuit comprises a driver 11. The driver 11 is connected to a connection point 111. For example, the driver 11 is a pull-down driver or a pull-up driver. For example, the calibration circuit of the implementation of the present disclosure may be used to perform ZQ calibration on the pull-down driver or, perform ZQ calibration on the pull-up driver.

In some implementations, the connection point 111 is configured to be connected to an external resistor R_{ZQ}. As shown in FIG. 1, the driver 11 and the external resistor R_{ZQ} are connected in series between a first voltage terminal 101 and a second voltage terminal 102. A voltage level of the first voltage terminal is different from a voltage level of the second voltage terminal. For example, the voltage level of the first voltage terminal is greater than the voltage level of the second voltage terminal. For example, the first voltage terminal is a power supply voltage terminal and the second voltage terminal is a ground terminal.

It is to be noted that, the external resistor described above may be a resistor provided alone or an equivalent resistor of other structures or members of the memory. For example, the resistance value of the external resistor may be 240 ohms. Of course, the scope of the present disclosure is not limited to a specific resistance value of the external resistor.

As shown in FIG. 1, the calibration circuit further comprises a multiplexing circuit 12. A first input terminal of the multiplexing circuit 12 is connected to the connection point 111, and a second input terminal of the multiplexing circuit 12 is configured to receive a reference voltage (for example, a first reference voltage V_{ref1}). The multiplexing circuit 12 is configured to, in response to a first selection signal Sₛₑₗₑ₁, output a connection point voltage (for example, a first connection point voltage Vᵢₒ₁) of the connection point 111 through a first output terminal of the multiplexing circuit and output the reference voltage through a second output terminal of the multiplexing circuit, and in response to a second selection signal Sₛₑₗₑ₂, output the connection point voltage through the second output terminal of the multiplexing circuit and output the reference voltage through the first output terminal of the multiplexing circuit.

As shown in FIG. 1, the calibration circuit further comprises a comparator 13. A first input terminal of the comparator 13 is connected to the first output terminal of the multiplexing circuit, and a second input terminal of the comparator 13 is connected to the second output terminal of the multiplexing circuit. The comparator 13 is configured to compare the connection point voltage with the reference voltage to obtain a comparison result.

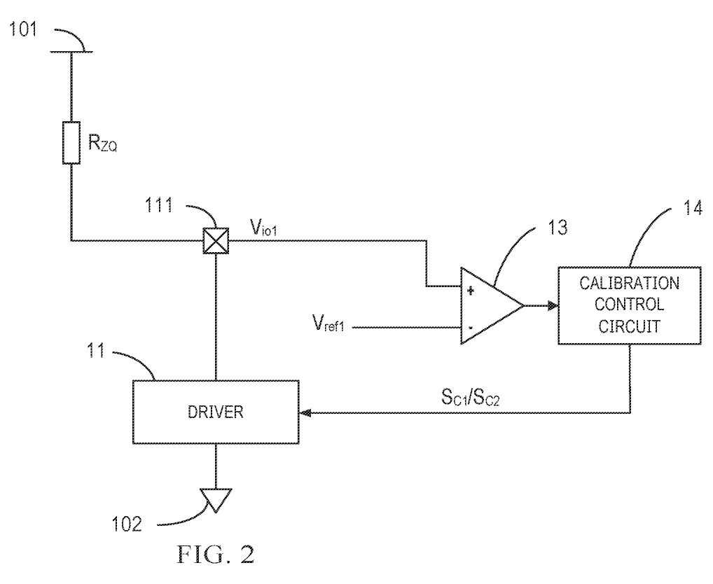

For example, FIG. 2 is a circuit connection view schematically showing a calibration circuit according to some implementations of the present disclosure when a multiplexing circuit is in one state. In the calibration circuit shown in FIG. 2, in response to the first selection signal Sₛₑₗₑ₁, the multiplexing circuit outputs the connection point voltage (for example, the first connection point voltage Vᵢₒ₁) of the connection point 111 to the first input terminal of the comparator 13 through the first output terminal of the multiplexing circuit, and outputs the reference voltage (for example, the first reference voltage V_{ref1}) to the second input terminal of the comparator 13 through the second output terminal of the multiplexing circuit. Therefore, the comparator 13 is configured to compare the connection point voltage with the reference voltage to obtain a first comparison result, wherein the first comparison result corresponds to the first selection signal.

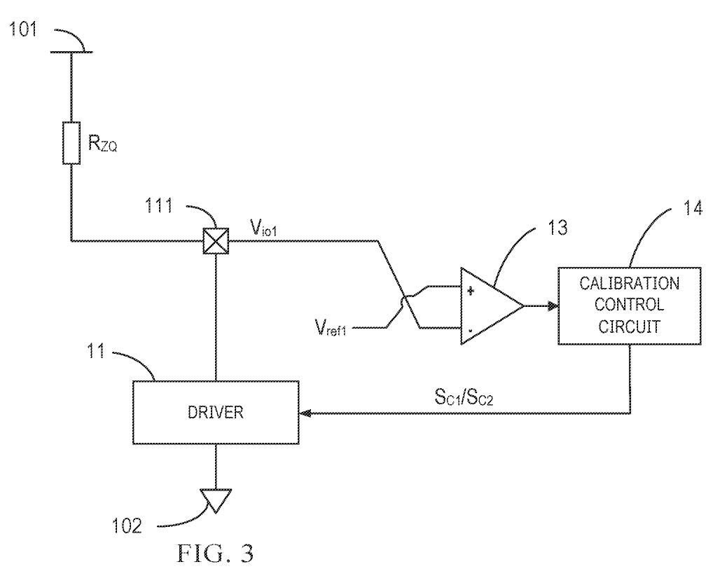

For example, FIG. 3 is a circuit connection view schematically showing a calibration circuit according to some implementations of the present disclosure when a multiplexing circuit is in another state. In the calibration circuit shown in FIG. 3, the multiplexing circuit receives the second selection signal Sₛₑₗₑ₂, and in response to the second selection signal Sₛₑₗₑ₂, outputs the connection point voltage (for example, the first connection point voltage Vᵢₒ₁) to the second input terminal of the comparator 13 through the second output terminal of the multiplexing circuit and outputs the reference voltage (for example, the first reference voltage V_{ref1}) to the first input terminal of the comparator 13 through the first output terminal of the multiplexing circuit. Therefore, the first comparator 13 is further configured to compare the connection point voltage with the reference voltage to obtain a second comparison result, wherein the second comparison result corresponds to the second selection signal.

Returning to FIG. 1, the calibration circuit further comprises a calibration control circuit 14. An input terminal of the calibration control circuit 14 is connected to an output terminal of the comparator 13, and an output terminal of the calibration control circuit 14 is connected to a control terminal of the driver 11. The calibration control circuit 14 is configured to calibrate the driver 11.

So far, a calibration circuit according to some implementations of the present disclosure has been provided. The calibration circuit comprises: a driver connected to a connection point; a multiplexing circuit, wherein a first input terminal of the multiplexing circuit is connected to the connection point, a second input terminal of the multiplexing circuit is configured to receive a reference voltage , the multiplexing circuit is configured to, in response to a first selection signal, output a connection point voltage of the connection point through a first output terminal of the multiplexing circuit and output the reference voltage through a second output terminal of the multiplexing circuit, and in response to a second selection signal, output the connection point voltage through the second output terminal of the multiplexing circuit and output the reference voltage through the first output terminal of the multiplexing circuit; a comparator, wherein a first input terminal of the comparator is connected to the first output terminal of the multiplexing circuit, and a second input terminal of the comparator is connected to the second output terminal of the multiplexing circuit; and a calibration control circuit, wherein an input terminal of the calibration control circuit is connected to an output terminal of the comparator, an output terminal of the calibration control circuit is connected to a control terminal of the driver, and the calibration control circuit is configured to calibrate the driver. In the calibration circuit, the connection point voltage and the reference voltage are transmitted to the comparator through the multiplexing circuit in two different states so that the comparator obtains two comparison results, and further the calibration control circuit calibrates the driver, which may improve the accuracy of ZQ calibration.

For example, the calibration control circuit 14 is configured to cyclically outputting a first resistance code S_{C1} based on the first comparison result to adjust a resistance value of the driver until a first loop exit condition is met, cyclically output a second resistance code S_{C2} based on the second comparison result to adjust a resistance value of the driver until a second loop exit condition is met, and calibrate the driver based on the first resistance code meeting the first loop exit condition and the second resistance code meeting the second loop exit condition. In the implementation, the calibration control circuit respectively performs cyclic processing based on the two comparison results respectively to obtain two resistance codes, and based on the two resistance codes, it is possible to reduce an adverse influence on the accuracy caused by the offset of the comparator, thereby improving the accuracy of ZQ calibration.

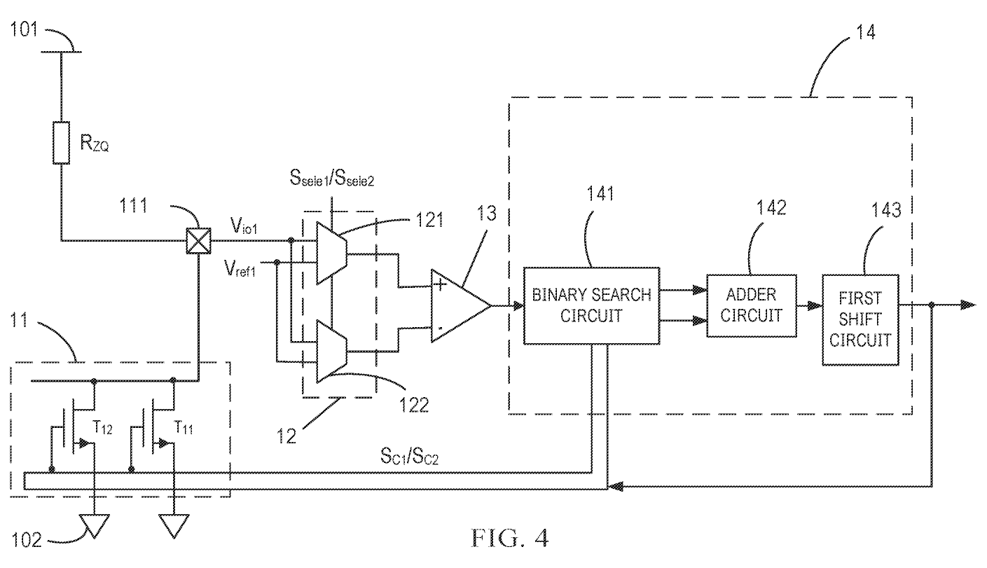

FIG. 4 is a circuit connection view schematically showing a calibration circuit according to other implementations of the present disclosure.

As shown in FIG. 4, the calibration circuit comprises: the driver 11, the multiplexing circuit 12, the comparator 13 and the calibration control circuit 14.

In some implementations, the driver 11 comprises one or more transistors. For example, as shown in FIG. 4, the driver 11 comprises a fifth transistor T₁₁, a sixth transistor T₁₂ arranged in parallel with the fifth transistor T₁₁, and the like. A first terminal of the fifth transistor T₁₁ is connected to the connection point 111, a second terminal of the fifth transistor T₁₁ is connected to the second voltage terminal 102, and a control terminal of the fifth transistor T₁₁is connected to the calibration control circuit 14. A first terminal of the sixth transistor T₁₂ is connected to the connection point 111, a second terminal of the sixth transistor T₁₂ is connected to the second voltage terminal 102, and a control terminal of the sixth transistor T₁₂ is connected to the calibration control circuit 14.

The calibration control circuit 14 may control a resistance value of the driver by controlling the number of transistors in the driver that are turned on. The calibration control circuit 14 is connected to a gate of the transistor through a signal line. The calibration control circuit 14 (for example, a binary search circuit of the calibration control circuit, which will be described later) may control the number of transistors that are turned on by outputting the first resistance code S_{C1} or the second resistance code S_{C2} to the transistors of the driver. Taking the driver 11 comprising two transistors T₁₁ and T₁₂ as an example, for example, the first resistance code S_{C1} output by the calibration control circuit 14 may be 00, 01, 10 or 11, where the binary number “0” represents that the transistor is turned off and the binary number “1” represents that the transistor is turned on. Thus, if the first resistance code is 00, it indicates that both transistors T₁₁ and T₁₂ are turned off. If the first resistance code is 01, it indicates that the sixth transistor T₁₂ is turned off and the fifth transistor T₁₁ is turned on. If the first resistance code is 10, it indicates that the sixth transistor T₁₂ is turned on and the fifth transistor T₁₁ is turned off. If the first resistance code is 11, it indicates that both transistors T₁₁ and T₁₂ are turned on. The second resistance code S_{C2} is similar to the first resistance code S_{C1}, which will not be described in detail here.

It is to be noted that, although FIG. 4 shows that the driver comprises two transistors, the scope of the present disclosure is not limited thereto, and the driver may comprise more transistors arranged in parallel.

As shown in FIG. 4, the multiplexing circuit 12 comprises a first multiplexer 121 and a second multiplexer 122. A first input terminal of the first multiplexer 121 is connected to the connection point 111. A second input terminal of the first multiplexer 121 is configured to receive the reference voltage (for example, the first reference voltage V_{ref1}). An output terminal of the first multiplexer 121 is connected to the first input terminal of the comparator 13. A control terminal of the first multiplexer 121 is configured to receive the first selection signal Sₛₑₗₑ₁ or the second selection signal Sₛₑₗₑ₂. A first input terminal of the second multiplexer 122 is connected to the connection point 111. A second input terminal of the second multiplexer 122 is configured to receive the reference voltage (for example, the first reference voltage V_{ref1}). An output terminal of the second multiplexer 122 is connected to the second input terminal of the comparator 13. A control terminal of the second multiplexer 122 is configured to receive the first selection signal Sₛₑₗₑ₁ or the second selection signal Sₛₑₗₑ₂.

Under the control of the first selection signal Sₛₑₗₑ₁, the connection point voltage Vᵢₒ₁ of the connection point 111 is output to the first input terminal of the comparator 13 through the first output terminal of the multiplexing circuit, and the reference voltage V_{ref1} is output to the second input terminal of the comparator 13 through the second output terminal of the multiplexing circuit. Under the control of the second selection signal Sₛₑₗₑ₂, the connection point voltage Vᵢₒ₁ is output to the second input terminal of the comparator 13 through the second output terminal of the multiplexing circuit, and the reference voltage V_{ref1} is output to the first input terminal of the comparator 13 through the first output terminal of the multiplexing circuit.

In some implementations, as shown in FIG. 4, the calibration control circuit 14 comprises: a binary search circuit 141, an adder circuit 142 and a first shift circuit 143.

As shown in FIG. 4, an input terminal of the binary search circuit 141 is connected to an output terminal of the comparator 13, and a first output terminal of the binary search circuit 141 is connected to the control terminal of the driver 11 (for example, control terminals of the fifth transistor T₁₁ and the sixth transistor T₁₂). The binary search circuit 141 is configured to, by way of binary search, cyclically output a first resistance code based on the first comparison result to adjust a resistance value of the driver until a first loop exit condition is met, and by way of the binary search, to cyclically output a second resistance code based on the second comparison result to adjust the resistance value of the driver until a second loop exit condition is met.

The first loop exit condition comprises a first predetermined number of cycle periods, and the second loop exit condition comprises a second predetermined number of cycle periods.

The first loop exit condition is the same as the second loop exit condition. At this time, the first predetermined number is equal to the second predetermined number. In this way, it is beneficial to improve the accuracy of calibration.

Of course, those skilled in the art may understand that the first loop exit condition may also be different from the second loop exit condition.

As shown in FIG. 4, a first input terminal of the adder circuit 142 is connected to a second output terminal of the binary search circuit 141, and the second input terminal of the adder circuit is connected to a third output terminal of the binary search circuit 141. The adder circuit 142 is configured to, based on the first resistance code meeting the first loop exit condition and the second resistance code meeting the first loop exit condition, perform an addition operation to obtain a sum of the first resistance code and the second resistance code.

As shown in FIG. 4, an input terminal of the first shift circuit 143 is connected to an output terminal of the adder circuit 142, and an output terminal of the first shift circuit 143 is connected to the control terminal (not shown) of the driver 11. The first shift circuit 143 is configured to shift a sum of the first resistance code and the second resistance code to the right (for example, to the right by one bit) to obtain an adjustment code. The adjustment code is half of the sum of the first resistance code and the second resistance code.

In this way, the calibration control circuit is implemented by the binary search circuit, the adder circuit and the first shift circuit described above. The calibration control circuit is configured to calculate an adjustment code based on the first resistance code meeting the first loop exit condition and the second resistance code meeting the second loop exit condition, and calibrate the driver based on the adjustment code, wherein the adjustment code is half of the sum of the first resistance code meeting the first loop exit condition and the second resistance code meeting the second loop exit condition.

It is to be noted that, the adjustment code described above may be used to adjust the current driver (for example, the driver 11 in FIG. 4). Alternatively, it may be used not to adjust the current drive, but to adjust other drives. For example, the calibration circuit shown in FIG. 4 obtains the above-described adjustment code through the above-described cyclic processing on the driver 11 and a corresponding operation, wherein the adjustment code may be transmitted to the driver 11 to adjust the driver 11. Alternatively, it may also be used not to be transmitted to the driver 11, but to be transmitted to drivers in other circuits or units to adjust the drivers in other circuits or units.

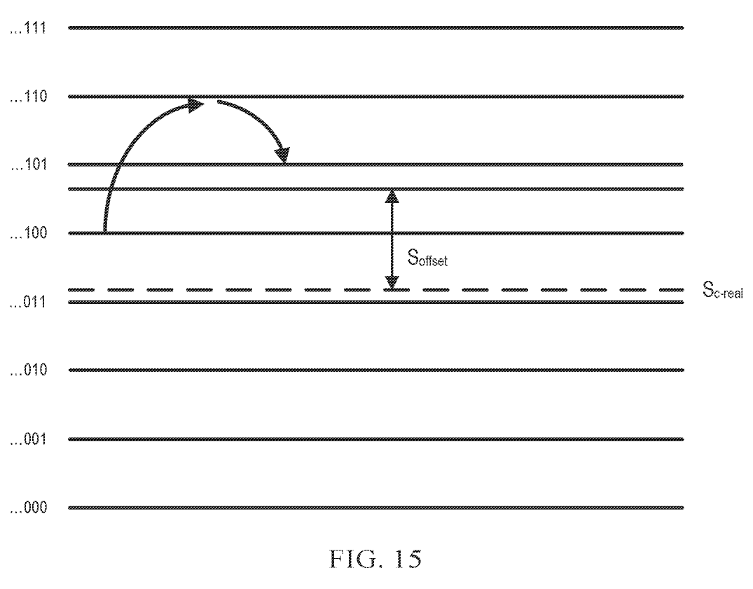

The operation principles of the above-described calibration circuit will be described in detail below in conjunction with FIGS. 15 to 18.

During the calibration process, the calibration control circuit starts calibration after receiving an on command, and adjusts the resistance value of the driver (for example, the pull-down driver) according to the comparison result of the comparator by way of a binary search method.

In the state of the multiplexing circuit shown in FIG. 2, assuming that the offset of the comparator is V_{offset}, if V_{ref1}+V_{offset} is greater than Vᵢₒ₁, indicating that the current resistance value of the driver is relatively small, the resistance value of the driver is increased by outputting the resistance code. If V_{ref1}+V_{offset} is less than Vᵢₒ₁, indicating that the current resistance value of the driver is relatively large, the resistance value of the driver is reduced by outputting the resistance code, and a cycle is performed until a first loop exit condition is met, for example, a first predetermined number of cycle periods. At this time, it is considered that the first resistance code S_{C1} corresponds to Vᵢₒ₁=V_{ref1}+V_{offset}.

For example, FIG. 15 shows the resistance code S_{c-real} corresponding to the voltage value of the comparator without offset and the resistance code S_{offset} corresponding to the offset of the comparator. At this time, the resistance code corresponding to the voltage value of the comparator with the offset is S_{c-real}+S_{offset}. As shown in FIG. 15, the resistance code comprises binary codes 000 to 111. In the binary search, first starting from the code 100, for example, the resistance of the driver is adjusted to the resistance value corresponding to the resistance code 100, and if it is found that V_{ref1}+V_{offset}is greater than Vᵢₒ₁ through a comparison result of the comparator, then the resistance code 110 is output to increase the resistance value of the driver. If it is found that V_{ref1}+V_{offset} is less than Vᵢₒ₁ through a comparison result of the comparator, then the resistance code is output to reduce the resistance value of the driver, and a cycle is performed until the adjustment of three cycles is met, so as to obtain a first resistance code S_{C1}.

Here, the number of bits of the resistance code is the number of cycle periods. For example, FIG. 15 shows a 3-bit resistance code, and the number of cycle periods is 3.

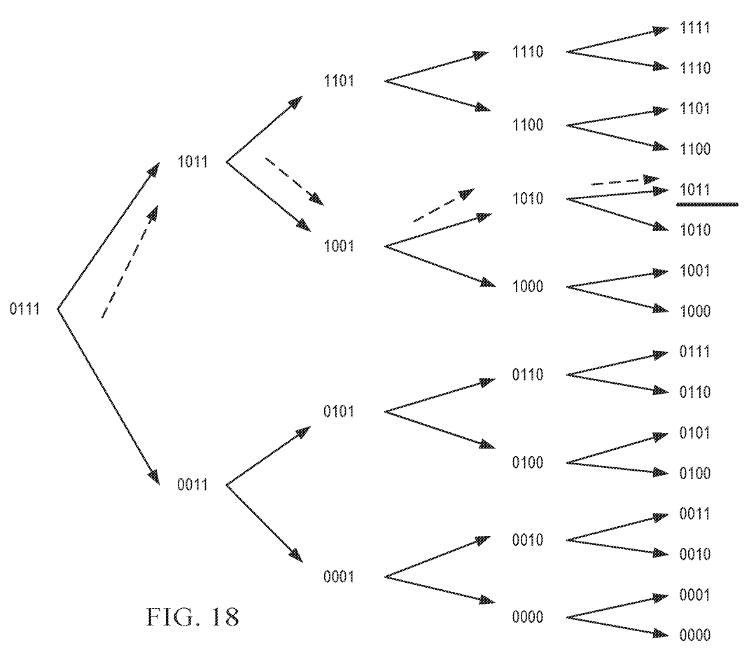

For another example, FIG. 18 shows a 4-bit resistance code, for example, 0000 to 1111. As can be seen from FIG. 18, starting from 0111, a first resistance code of 1011 can be obtained after four cycles of cyclic processing.

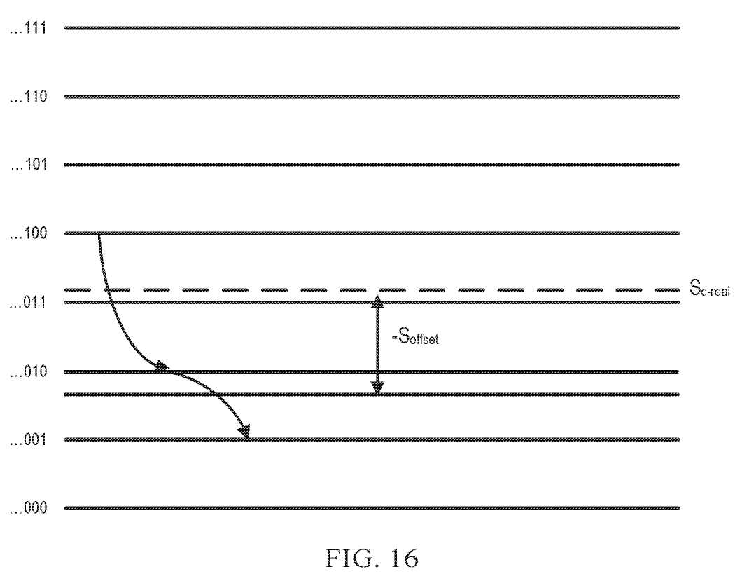

Next, a transmission line of the multiplexing circuit is replaced by the circuit shown in FIG. 3. Since the offset of the comparator has been assumed to be V_{offset} previously, the resistance code corresponding to the voltage value of the comparator in the case where there is the offset is S_{c-real}-S_{offset} in the state of the multiplexing circuit shown in FIG. 3, for example, as shown in FIG. 16. Then, a binary search method is performed, and a cycle process of the binary search method is similar to the cycle process described previously. By way of the binary search method, the second resistance code S_{C2} is obtained. Here, it may be considered that the second resistance code S_{C2} corresponds to Vᵢₒ₁=V_{ref1}-V_{offset}.

Next, the adder circuit performs an addition operation on the first resistance code and the second resistance code to obtain the sum S_{C1}+S_{C2} of the first resistance code and the second resistance code. Here, S_{C1}+S_{C2} corresponds to (V_{ref1}+V_{offset})+(V_{ref1}-V_{offset})=2V_{reff1}.

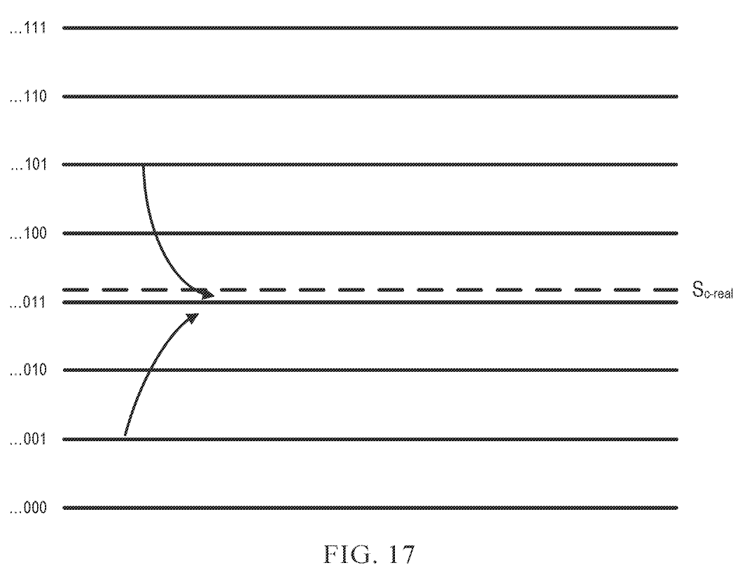

Next, the first shift circuit shifts the sum S_{C1}+S_{C2} of the first resistance code and the second resistance code to the right by one bit to obtain an adjustment code, wherein the adjustment code is (S_{C1}+S_{C2})/2, which corresponds to the reference voltage V_{ref1}. As shown in FIG. 17, the adjustment code (S_{C1}+S_{C2})/2 is relatively close to the resistance code S_{c-real} corresponding to the voltage value of the comparator in the case where there is no offset.

In this way, by adjusting the resistance value of the driver through the resistance code (S_{C1}+S_{C2})/2, it is possible to reduce the influence of the offset value of the comparator on ZQ calibration, thereby improving the accuracy of ZQ calibration.

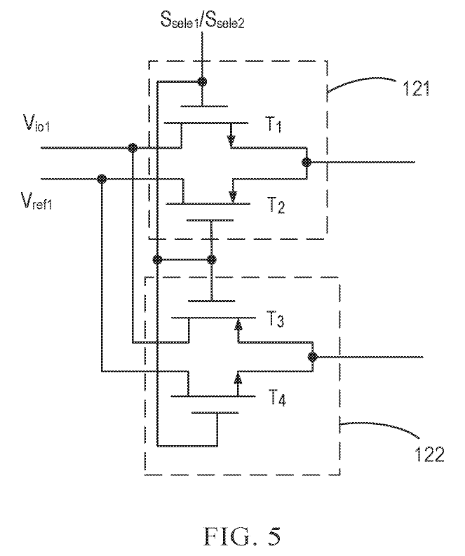

FIG. 5 is a circuit connection view schematically showing a multiplexing circuit according to some implementations of the present disclosure.

As shown in FIG. 5, the multiplexing circuit comprises a first multiplexer 121 and a second multiplexer 122.

For example, as shown in FIG. 5, the first multiplexer 121 comprises a first transistor T₁ and a second transistor T₂.

A first terminal of the first transistor T₁ is configured to receive the connection point voltage (for example, the first connection point voltage Vᵢₒ₁). A second terminal of the first transistor T₁ serves as the output terminal of the first multiplexer 121. A control terminal of the first transistor T₁ is configured to receive the first selection signal Sₛₑₗₑ₁ or the second selection signal Sₛₑₗₑ₂.

A first terminal of the second transistor T₂ is configured to receive the reference voltage (for example, the first reference voltage V_{ref1}). A second terminal of the second transistor T₂ is connected to the second terminal of the first transistor T₁. A control terminal of the second transistor T₂ is connected to the control terminal of the first transistor T₁. A conductivity type of the second transistor is opposite to a conductivity type of the first transistor. For example, the first transistor is an NMOS (Negative channel Metal Oxide Semiconductor) transistor, and the second transistor is a PMOS (Positive channel Metal Oxide Semiconductor) transistor. Alternatively, the first transistor is a PMOS transistor and the second transistor is an NMOS transistor.

In this way, under the control of the first selection signal Sₛₑₗₑ₁ or the second selection signal Sₛₑₗₑ₂, the first transistor is turned on and the second transistor is turned off, or the first transistor is turned off and the second transistor is turned on. Since only one of these two transistors is turned on, one of the connection point voltage and the reference voltage is transmitted to the comparator.

For example, as shown in FIG. 5, the second multiplexer 122 comprises a third transistor T₃ and a fourth transistor T₄.

A first terminal of the third transistor T₃ is connected to the first terminal of the first transistor T₁. A second terminal of the third transistor T₃ serves as the output terminal of the second multiplexer 122. A control terminal of the third transistor T₃ is connected to the control terminal of the first transistor T₁. A conductivity type of the third transistor is opposite to the conductivity type of the first transistor. For example, the first transistor is an NMOS transistor, and the third transistor is a PMOS transistor. Alternatively, the first transistor is a PMOS transistor, and the third transistor is an NMOS transistor.

A first terminal of the fourth transistor T₄ is connected to the first terminal of the second transistor T₂. A second terminal of the fourth transistor T₄ is connected to the second terminal of the third transistor T₃. A control terminal of the fourth transistor T₄ is connected to the control terminal of the first transistor T₁. A conductivity type of the fourth transistor is the same as the conductivity type of the first transistor. For example, the first transistor is an NMOS transistor, and the fourth transistor is an NMOS transistor. Alternatively, the first transistor is a PMOS transistor, and the fourth transistor is a PMOS transistor.

In this way, under the control of the first selection signal Sₛₑₗₑ₁ or the second selection signal Sₛₑₗₑ₂, the third transistor is turned on and the fourth transistor is turned off, or the third transistor is turned off and the fourth transistor is turned on. Since only one of these two transistors is turned on, one of the connection point voltage and the reference voltage is transmitted to the comparator.

Therefore, by way of the structure of the multiplexing circuit shown in FIG. 5, it can be achieved that under the control of the first selection signal Sₛₑₗₑ₁ or the second selection signal Sₛₑₗₑ₂, the multiplexing circuit transmits the connection point voltage to the first input terminal of the comparator and the reference voltage to the second input terminal of the comparator, or transmits the connection point voltage to the second input terminal of the comparator and the reference voltage to the first input terminal of the comparator.

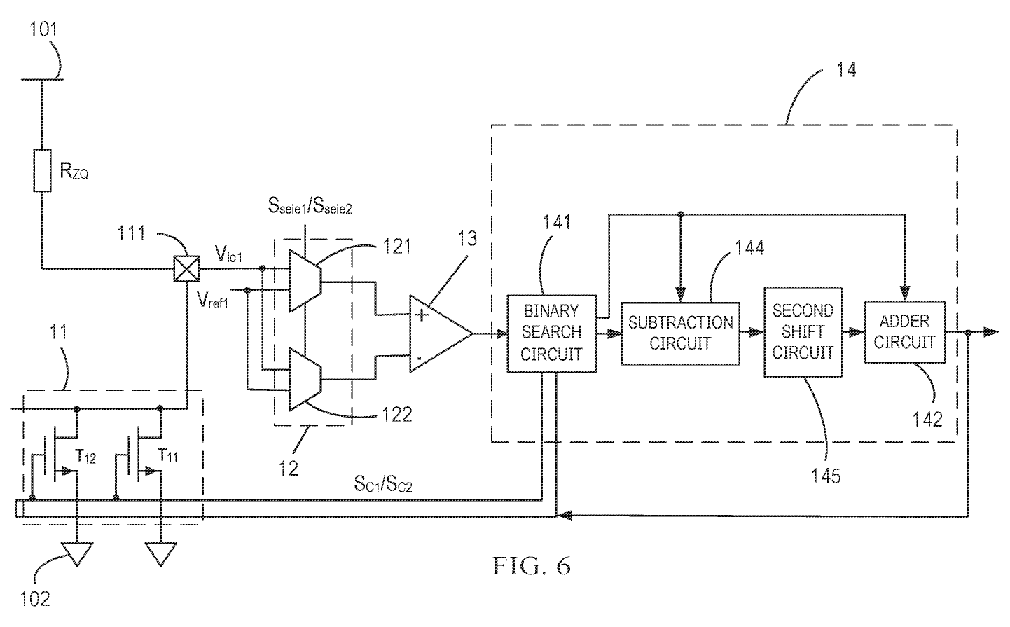

FIG. 6 is a circuit connection view schematically showing a calibration circuit according to other implementations of the present disclosure.

As shown in FIG. 6, the calibration circuit comprises: the driver 11, the multiplexing circuit 12, the comparator 13 and the calibration control circuit 14.

As shown in FIG. 6, the calibration control circuit 14 comprises a binary search circuit 141. An input terminal of the binary search circuit 141 is connected to the output terminal of the comparator 13. A first output terminal of the binary search circuit is connected to the control terminal of the driver 11. The binary search circuit 141 is configured to, by way of binary search, cyclically output a first resistance code based on the first comparison result to adjust a resistance value of the driver until a first loop exit condition is met, and to, by way of binary search, cyclically output a second resistance code based on the second comparison result to adjust the resistance value of the driver until a second loop exit condition is met.

As shown in FIG. 6, the calibration control circuit 14 further comprises a subtraction circuit 144. A first input terminal of the subtraction circuit 144 is connected to a second output terminal of the binary search circuit 141. A second input terminal of the subtraction circuit 144 is connected to a third output terminal of the binary search circuit 141. The subtraction circuit 144 is configured to perform a subtraction operation based on the first resistance code meeting the first loop exit condition and the second resistance code meeting the second loop exit condition to obtain a difference between the first resistance code and the second resistance code. Here, the binary search circuit 141 outputs the first resistance code meeting the first loop exit condition through its second output terminal and outputs the second resistance code meeting the second loop exit condition through its third output terminal.

As shown in FIG. 6, the calibration control circuit 14 further comprises a second shift circuit 145. An input terminal of the second shift circuit 145 is connected to an output terminal of the subtraction circuit 144. The second shift circuit 145 is configured to shift the difference between the first resistance code and the second resistance code to the right (for example, to the right by one bit) to obtain an offset code. The offset code is half of the difference between the first resistance code and the second resistance code.

As shown in FIG. 6, the calibration control circuit 14 further comprises an adder circuit 142. A first input terminal of the adder circuit 142 is connected to an output terminal of the second shift circuit. A second input terminal of the adder circuit is connected to the third output terminal of the binary search circuit 141. The adder circuit 142 is configured to perform an addition operation based on the offset code and the second resistance code meeting the second loop exit condition to obtain an adjustment code. The adjustment code is used to perform ZQ calibration on the driver. As described previously, the adjustment code is half of the sum of the first resistance code and the second resistance code.

In the previous description, if the second output terminal of the binary search circuit 141 outputs the first resistance code meeting the first loop exit condition, and the third output terminal of the binary search circuit 141 outputs the second resistance code meeting the second loop exit condition, then the adder circuit 142 performs an addition operation based on the offset code and the second resistance code meeting the second loop exit condition to obtain the adjustment code.

In this way, the calibration control circuit is implemented by the binary search circuit, the subtraction circuit, the second shift circuit and the adder circuit described above. The calibration control circuit is configured to calculate an offset code based on the first resistance code meeting the first loop exit condition and the second resistance code meeting the second loop exit condition, calculate an adjustment code based on the offset code and the second resistance code meeting the second loop exit condition, and calibrate the driver based on the adjustment code, wherein the offset code is half of the difference between the first resistance code meeting the first loop exit condition and the second resistance code meeting the second loop exit condition.

The operation principles of the calibration circuit described above will be described in detail below.

During the calibration process, the calibration control circuit starts calibration after receiving an on command, and adjusts a resistance value of the driver (for example, a pull-down driver) according to a comparison result of the comparator by way of a binary search method.

In the previous description, the process of obtaining the first resistance code meeting the first loop exit condition and the second resistance code meeting the second loop exit condition has been described in conjunction with FIGS. 15, 16 and 18, which will not be described in detail here.

Next, the subtraction circuit performs a subtraction operation on the first resistance code and the second resistance code to obtain the difference S_{C1}-S_{C2} between the first resistance code and the second resistance code. Here, S_{C1}-S_{C2} corresponds to (V_{ref1}+V_{offset})-(V_{ref1}-V_{offset})=2V_{offset}.

Next, the second shift circuit shifts the difference between the first resistance code and the second resistance code to the right by one bit to obtain an offset code (S_{C1}-S_{C2})/2, wherein the offset code (S_{C1}-S_{C2})/2 corresponds to 2V_{offset}/2=V_{offset}.

Next, based on the offset code and the second resistance code meeting the second loop exit condition, the adder circuit performs an addition operation to obtain an adjustment code, for example, (S_{C1}-S_{C2})/2+S_{C2}=(S_{C1}+S_{C2})/2. Since the second resistance code S_{C2} corresponds to Vᵢₒ₁=V_{ref1}-V_{offset}, the adjustment code corresponds to Vᵢₒ₁+V_{offset}=V_{ref1}-V_{offset}+V_{offset}=V_{ref1}.

As shown in FIG. 17, the adjustment code (S_{C1}+S_{C2})/2 is relatively close to the resistance code S_{c-real} corresponding to the voltage value of the comparator in the case where there is no offset.

In this way, by adjusting the resistance value of the driver through the resistance code (S_{C1}+S_{C2})/2, it is possible to reduce the influence of the offset value of the comparator on ZQ calibration, thereby improving the accuracy of ZQ calibration.

In other implementations, since S_{C1} corresponds to Vᵢₒ₁=V_{ref1}+V_{offset}, it is also possible to allow that the adjustment code is S_{C1}-(S_{C1}-S_{C2})/2=(S_{C1}+S_{C2})/2. Since the first resistance code S_{C1} corresponds to Vᵢₒ₁=V_{ref1}+V_{offset}, the adjustment code corresponds to Vᵢₒ₁-V_{offset}=V_{ref1}+V_{offset}-V_{offset}=V_{ref1}. For example, the adder circuit in FIG. 6 may be replaced by another subtraction circuit different from the subtraction circuit 144, and the binary search circuit may input the first resistance code meeting the first loop exit condition to the another subtraction circuit, and the second shift circuit may also input the offset code (S_{C1}-S_{C2})/2 to the another subtraction circuit, so that the another subtraction circuit may perform the subtraction operation described above to obtain the adjustment code. It is also possible to reduce the influence of the offset value of the comparator on ZQ calibration, thereby improving the accuracy of ZQ calibration.

It is to be noted that, although the influence of the offset value of the comparator on ZQ calibration is reduced in conjunction with a method such as an adder circuit and/or a subtraction circuit, the scope of the present disclosure is not limited thereto. The present disclosure may also use other types of circuits, as long as the influence of the offset value of the comparator on ZQ calibration can be reduced.

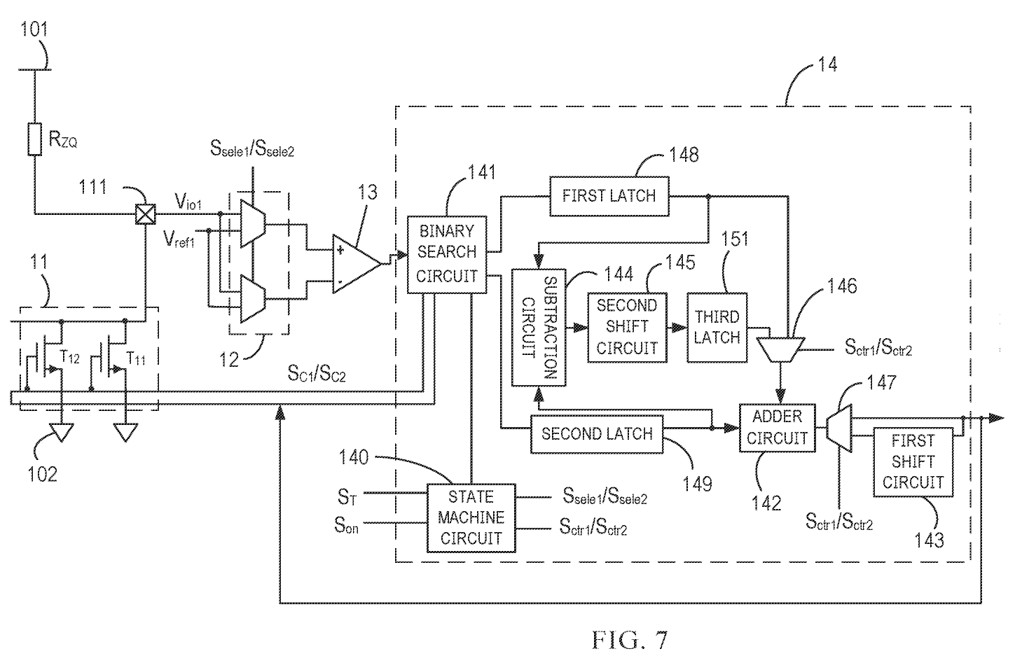

FIG. 7 is a circuit connection view schematically showing a calibration circuit according to other implementations of the present disclosure.

As shown in FIG. 7, the calibration circuit comprises: the driver 11, the multiplexing circuit 12, the comparator 13 and the calibration control circuit 14.

As shown in FIG. 7, the calibration control circuit 14 comprises a binary search circuit 141. An input terminal of the binary search circuit 141 is connected to an output terminal of the comparator 13. A first output terminal of the binary search circuit 141 is connected to the control terminal of the driver 11.

As shown in FIG. 7, the calibration control circuit 14 further comprises an adder circuit 142. A first input terminal of the adder circuit 142 is connected to a second output terminal of the binary search circuit 141. A second input terminal of the adder circuit 142 is connected to a third output terminal of the binary search circuit 141.

As shown in FIG. 7, the calibration control circuit 14 further comprises a first shift circuit 143. An input terminal of the first shift circuit 143 is connected to an output terminal of the adder circuit 142. An output terminal of the first shift circuit 143 is connected to the control terminal of the driver 11.

Here, the binary search circuit 141, the adder circuit 142 and the first shift circuit 143 can implement the same or similar calibration control logic as the calibration control circuit 14 shown in FIG. 4.

As shown in FIG. 7, the calibration control circuit 14 further comprises a subtraction circuit 144. A first input terminal of the subtraction circuit 144 is connected to the second output terminal of the binary search circuit 141. The second input terminal of the subtraction circuit 144 is connected to the third output terminal of the binary search circuit 141.

As shown in FIG. 7, the calibration control circuit 14 further comprises a second shift circuit 145. An input terminal of the second shift circuit 145 is connected to an output terminal of the subtraction circuit 144. An output terminal of the second shift circuit 145 is connected to the first input terminal of the adder circuit 142.

Here, the binary search circuit 141, the subtraction circuit 144, the second shift circuit 145 and the adder circuit 142 can implement the same or similar calibration control logic as the calibration control circuit 14 shown in FIG. 6.

Therefore, the calibration control circuit 14 shown in FIG. 7 can implement the two calibration control logics described above, one of which may be used for ZQ calibration as required.

In some implementations, as shown in FIG. 7, the calibration control circuit 14 further comprises a third multiplexer 146. The third multiplexer 146 is arranged between the second shift circuit 145 and the adder circuit 142, and between the binary search circuit 141 and the adder circuit 142. A first input terminal of the third multiplexer 146 is connected to the second output terminal of the binary search circuit 141. A second input terminal of the third multiplexer 146 is connected to the output terminal of the second shift circuit 145. An output terminal of the third multiplexer 146 is connected to the first input terminal of the adder circuit 142. A control terminal of the third multiplexer 146 is configured to receive a first control signal S_{ctr1} or a second control signal S_{ctr2}.

The third multiplexer 146 is configured to transmit the first resistance code to the adder circuit in response to the first control signal, and transmit the offset code to the adder circuit in response to the second control signal. Since the third multiplexer transmits the first resistance code to the adder circuit in response to the first control signal, the adder circuit can perform an addition operation on the first resistance code and the second resistance code received from the binary search circuit to obtain the sum S_{C1}+S_{C2} of the first resistance code and the second resistance code. Since the third multiplexer transmits the offset code to the adder circuit in response to the second control signal, the adder circuit can perform an addition operation on the offset code and the second resistance code received from the binary search circuit to obtain an adjustment code (S_{C1}+S_{C2})/2. Therefore, the third multiplexer can transmit different codes to the adder circuit through different control signals, so that the adder circuit can perform different addition operations.

In some implementations, as shown in FIG. 7, the calibration control circuit 14 further comprises a fourth multiplexer 147. The fourth multiplexer 147 is arranged between the adder circuit 142 and the first shift circuit 143. An input terminal of the fourth multiplexer 147 is connected to the output terminal of the adder circuit 142. A first output terminal of the fourth multiplexer 147 is connected to the control terminal of the driver 11. A second output terminal of the fourth multiplexer 147 is connected to the input terminal of the first shift circuit 143. A control terminal of the fourth multiplexer 147 is configured to receive the first control signal S_{ctr1} or the second control signal S_{ctr2}.

The fourth multiplexer 147 is configured to transmit the sum of the first resistance code and the second resistance code output by the adder circuit to the first shift circuit in response to the first control signal, and output the adjustment code in response to the second control signal. In the implementation, the fourth multiplexer transmits the sum of the first resistance code and the second resistance code output by the adder circuit to the first shift circuit in response to the first control signal, so that the first shift circuit shifts the sum S_{C1}+S_{C2}of the first resistance code and the second resistance code to the right to obtain an adjustment code, and outputs the adjustment code to the control terminal of the driver, thereby implementing ZQ calibration of the driver. The fourth multiplexer outputs the adjustment code to the control terminal of the driver in response to the second control signal, which also implements ZQ calibration of the driver.

In some implementations, as shown in FIG. 7, the calibration control circuit 14 further comprises a state machine circuit 140. A first input terminal of the state machine circuit 140 is configured to receive an on command Sₒₙ. A first output terminal of the state machine circuit 140 is configured to output the first selection signal Sₛₑₗₑ₁ or the second selection signal Sₛₑₗₑ₂. A second output terminal of the state machine circuit 140 is configured to output the first control signal S_{ctr1} or the second control signal S_{ctr2}. The state machine circuit 140 is configured to, based on the on command Sₒₙ, output the first selection signal or the second selection signal and output the first control signal or the second control signal. The control of the multiplexing circuit 12, the third multiplexer 146 and the fourth multiplexer 147 is implemented by outputting the first selection signal or the second selection signal and outputting the first control signal or the second control signal, thereby implementing the control of ZQ calibration.

The on command may be a signal sent by a timer inside the memory. In this way, it is possible to start a calibration process once every fixed time interval. For another example, the on command may be a ZQ on command issued by the user terminal.

In some implementations, as shown in FIG. 7, a second input terminal of the state machine circuit 140 is configured to receive a temperature change signal S_{T}. The state machine circuit 140 is also configured to, based on the on command Sₒₙ and the temperature change signal S_{T}, output the first selection signal or the second selection signal and output the first control signal or the second control signal. For example, the state machine circuit 140 starts ZQ calibration based on the on command Sₒₙ and the temperature change signal S_{T}. By incorporating the temperature change signal as a starting factor of starting ZQ calibration, different calibration control logics are used based on different temperature changes.

For example, the state machine circuit 140 is configured to output the first control signal in response to the temperature change signal indicating that a change amplitude of a temperature of a memory within a predetermined time is greater than or equal to an amplitude threshold, and output the second control signal in response to the temperature change signal indicating that the change amplitude of the temperature of the memory within the predetermined time is less than the amplitude threshold. In the case where the state machine circuit outputs the first control signal, the calibration control circuit 14 can use the same or similar calibration control logic as the calibration control circuit shown in FIG. 4. In the case where the state machine circuit outputs the second control signal, the calibration control circuit 14 can use the same or similar calibration control logic as the calibration control circuit shown in FIG. 6.

In the above-described implementation, if the temperature change signal indicates that the change amplitude of the temperature of the memory within the predetermined time is greater than or equal to the amplitude threshold, it indicates that the current memory is greatly affected by the temperature, and then the first resistance code meeting the first loop exit condition and the second resistance code meeting the second loop exit condition reobtained by way of binary search, so as to completely perform ZQ calibration again. If the temperature change signal indicates that the change amplitude of the temperature of the memory within the predetermined time is less than the amplitude threshold, it indicates that the current memory is not greatly affected by the temperature, it is possible to use the offset code (S_{C1}-S_{C2})/2 that has been obtained previously and the second resistance code meeting the second loop exit condition that is reobtained so as to perform ZQ calibration again. This can improve the operation speed and reduce the time cost.

It is to be noted that, the above-described predetermined time may be set according to actual needs, and the scope of the present disclosure is not limited to a specific value of the predetermined time.

It is also to be noted that, the above-described amplitude threshold may be set according to actual needs, and the scope of the present disclosure is not limited to a specific value of the amplitude threshold.

For example, the memory is internally provided with a temperature sensor, which can detect a temperature of the current memory. The monitoring time interval and the threshold of the severity of the temperature change can be defined by the user, for example, the predetermined time and the amplitude threshold described above can be defined by the user. For example, every 32 milliseconds (as a predetermined time), the temperature sensor samples the temperature data once, and compares the temperature data before sampling with the temperature data after sampling. When the temperature change exceeds 5℃ (as an amplitude threshold), it is considered as a great change, and a corresponding temperature change signal is generated. If the calibration control circuit receives a temperature change signal indicating a great temperature change, the first resistance code meeting the first loop exit condition and the second resistance code meeting the second loop exit condition are reobtained by way of binary search,, the adjustment code is obtained by an addition operation, and the offset code is obtained by a subtraction operation. Before receiving a new temperature change signal, the subsequent calibration process may use the offset code that has been obtained previously and the second resistance code that is reobtained for ZQ calibration.

In some implementations, as shown in FIG. 7, the calibration control circuit 14 further comprises a first latch 148. The first latch 148 is arranged between the binary search circuit 141 and the third multiplexer 146, and between the binary search circuit 141 and the subtraction circuit 144. An input terminal of the first latch 148 is connected to the second output terminal of the binary search circuit 141. An output terminal of the first latch 148 is connected to the first input terminal of the third multiplexer 146 and the first input terminal of the subtraction circuit 144. The first latch 148 is configured to latch the first resistance code meeting the first loop exit condition. This facilitates subsequent use of the first resistance code.

In some implementations, as shown in FIG. 7, the calibration control circuit 14 further comprises a second latch 149. The second latch 149 is arranged between the binary search circuit 141 and the adder circuit 142 and between the binary search circuit 141 and the subtraction circuit 144. An input terminal of the second latch 149 is connected to the third output terminal of the binary search circuit 141. An output terminal of the second latch 149 is connected to the second input terminal of the adder circuit 142 and the second input terminal of the subtraction circuit 144. The second latch 149 is configured to latch the second resistance code meeting the second loop exit condition. This facilitates subsequent use of the second resistance code.

In some implementations, as shown in FIG. 7, the calibration control circuit further comprises a third latch 151. The third latch 151 is arranged between the second shift circuit 145 and the third multiplexer 146. An input terminal of the third latch 151 is connected to the output terminal of the second shift circuit 145. An output terminal of the third latch 151 is connected to the second input terminal of the third multiplexer 146. The third latch 151 is configured to latch the offset code. This facilitates subsequent use of the offset code. For example, in a case where the change amplitude of the temperature of the memory within the predetermined time is less than the amplitude threshold, it is possible to use the offset code latched in the third latch 151 and the second resistance code meeting the second loop exit condition that is reobtained so as to perform ZQ calibration again.

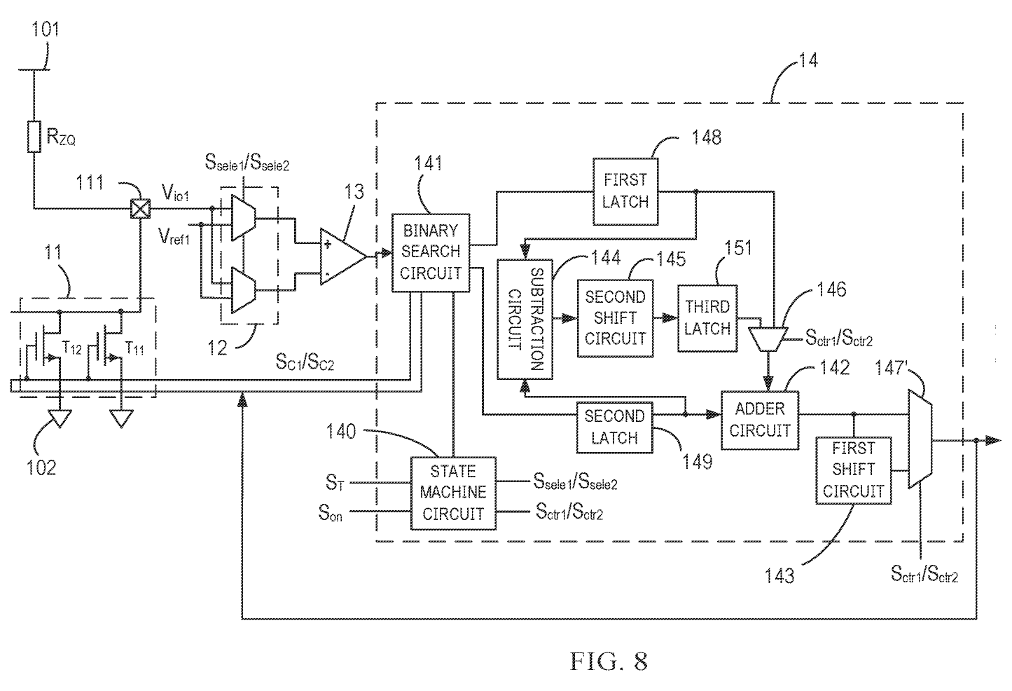

FIG. 8 is a circuit connection view schematically showing a calibration circuit according to other implementations of the present disclosure.

Compared with the calibration control circuit shown in FIG. 7, the calibration control circuit shown in FIG. 8 comprises a fourth multiplexer 147'. A connection circuit of the fourth multiplexer 147' is different from a connection circuit of the fourth multiplexer 147 in FIG. 7. As shown in FIG. 8, a first input terminal of the fourth multiplexer 147' is connected to the output terminal of the adder circuit 142. A second input terminal of the fourth multiplexer 147' is connected to the output terminal of the first shift circuit 143. The input terminal of the first shift circuit 143 is connected to the output terminal of the adder circuit 142. An output terminal of the fourth multiplexer 147' is connected to the control terminal of the driver. A control terminal of the fourth multiplexer 147' is configured to receive the first control signal S_{ctr1} or the second control signal S_{ctr2}.

The fourth multiplexer 147' is configured to output the adjustment code output by the first shift circuit 143 in response to the first control signal, and output the adjustment code output by the adder circuit 142 in response to the second control signal.

For example, the third multiplexer 146 transmits the first resistance code to the adder circuit 142 in response to the first control signal, the binary search circuit 141 transmits the second resistance code to the adder circuit 142, the adder circuit performs an addition operation on the first resistance code and the second resistance code to obtain the sum of the first resistance code and the second resistance cod. Then, the adder circuit transmits the sum to the first shift circuit 143. The first shift circuit shifts the sum of the first resistance code and the second resistance code to the right by one bit to obtain an adjustment code, and the fourth multiplexer 147' outputs the adjustment code to the driver in response to the first control signal to perform ZQ calibration on the driver.

For another example, the third multiplexer 146 transmits the offset code to the adder circuit in response to the second control signal, the binary search circuit 141 transmits the second resistance code to the adder circuit 142, the adder circuit performs an addition operation on the offset code and the second resistance code received from the binary search circuit to obtain an adjustment code. The fourth multiplexer 147' outputs the adjustment code to the driver in response to the second control signal to perform ZQ calibration on the driver.

Therefore, the fourth multiplexer 147' outputs the adjustment code for calibrating the driver, thereby achieving ZQ calibration of the driver.

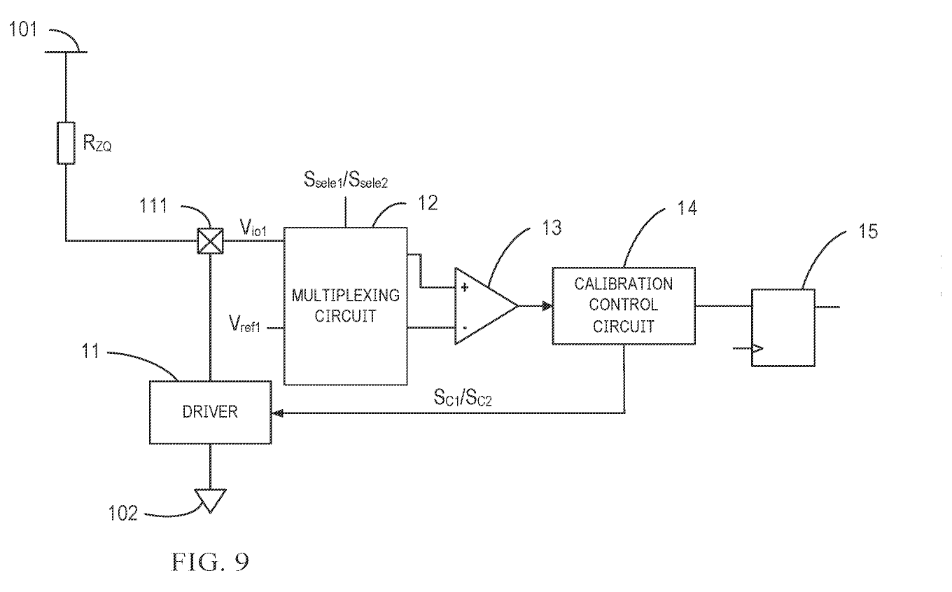

FIG. 9 is a circuit connection view schematically showing a calibration circuit according to other implementations of the present disclosure.

Compared with the calibration circuit shown in FIG. 1, the calibration circuit shown in FIG. 9 further comprises a register circuit 15 in addition to the driver 11, the multiplexing circuit 12, the comparator 13 and the calibration control circuit 14. The register circuit 15 is connected to the calibration control circuit 14. The register circuit 15 is configured to register the adjustment code output by the calibration control circuit 14, and output the adjustment code to a driver (for example, a next driver). For example, the register circuit 15 is a register.

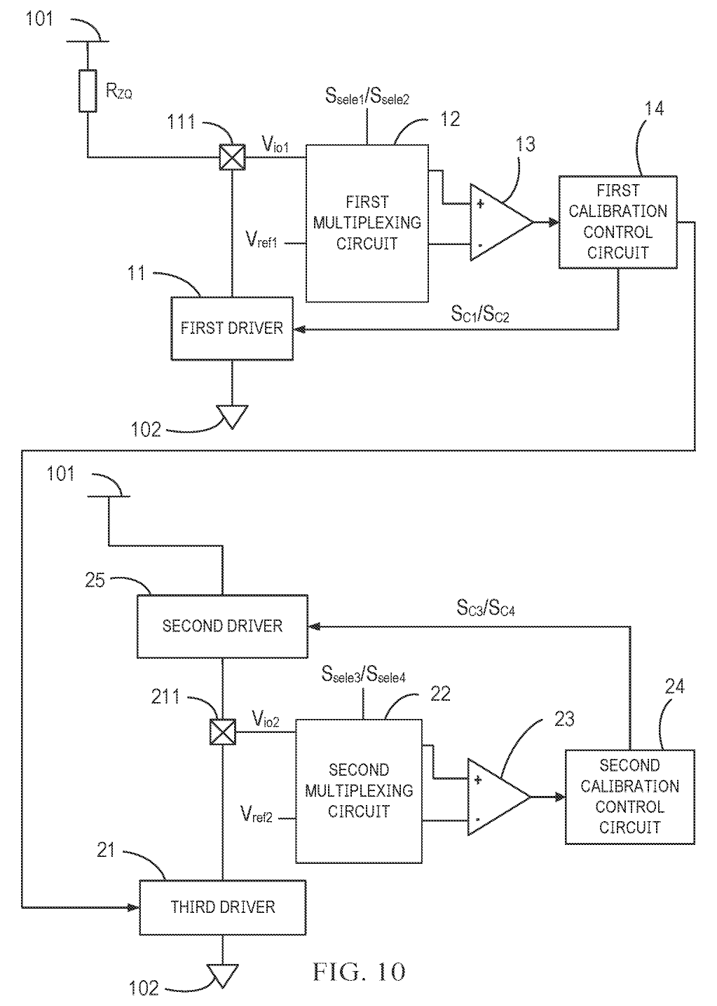

FIG. 10 is a circuit connection view schematically showing a calibration circuit according to other implementations of the present disclosure.

As shown in FIG. 10, the calibration circuit comprises: a first driver 11, a first multiplexing circuit 12, a first comparator 13 and a first calibration control circuit 14. Here, the first driver 11, the first multiplexing circuit 12, the first comparator 13 and the first calibration control circuit 14 are the same as or similar to the driver 11, the multiplexing circuit 12, the comparator 13 and the calibration control circuit 14 described previously, which will not be described in detail here again.

As shown in FIG. 10, the calibration circuit further comprises a second driver 25, a third driver 21, a second multiplexing circuit 22, a second comparator 23 and a second calibration control circuit 24. In addition, FIG. 10 also shows a first connection point 111 and a second connection point 211.

The second driver 25 is electrically connected to the second connection point 211. The third driver 21 is electrically connected to the second connection point 211. The second driver 25 and the third driver 21 are connected in series between a first voltage terminal 101 and a second voltage terminal 102. A control terminal of the third driver 21 is electrically connected to an output terminal of the first calibration control circuit 14. The third driver 21 is the same as the first driver 11. The third driver 21 is calibrated by the first calibration control circuit 14. For example, the second driver 25 is a pull-up driver, and the third driver 21 is a pull-down driver.

A first input terminal of the second multiplexing circuit 22 is connected to the second connection point 211, and a second input terminal of the second multiplexing circuit 22 is configured to receive a second reference voltage V_{ref2}. The second multiplexing circuit 22 is configured to, in response to a third selection signal Sₛₑₗₑ₃, output a connection point voltage (which may be referred to as a second connection point voltage Vᵢₒ₂) of the second connection point 211 through a first output terminal of the second multiplexing circuit and output the second reference voltage V_{ref2} through a second output terminal of the second multiplexing circuit, and in response to a fourth selection signal Sₛₑₗₑ₄, output the second connection point voltage through the second output terminal of the second multiplexing circuit and output the second reference voltage through the first output terminal of the second multiplexing circuit.

A first input terminal of the second comparator 23 is connected to the first output terminal of the second multiplexing circuit, and a second input terminal of the second comparator 23 is connected to the second output terminal of the second multiplexing circuit. The second comparator 23 is configured to compare the second connection point voltage with the second reference voltage to obtain a comparison result.

For example, the second comparator 23 is configured to compare the second connection point voltage with the second reference voltage to obtain a third comparison result, wherein the third comparison result corresponds to the third selection signal.

For another example, the second comparator 23 is configured to compare the second connection point voltage with the second reference voltage to obtain a fourth comparison result, wherein the fourth comparison result corresponds to the fourth selection signal.

An input terminal of the second calibration control circuit 24 is connected to an output terminal of the second comparator 23, and an output terminal of the second calibration control circuit 24 is connected to a control terminal of the second driver 25. The second calibration control circuit 24 is configured to calibrate the second driver 25.

So far, a calibration circuit according to other implementations of the present disclosure has been provided. The calibration circuit comprises a first driver, a first multiplexing circuit, a first comparator, a first calibration control circuit, a second driver, a third driver, a second multiplexing circuit, a second comparator and a second calibration control circuit. ZQ calibration of the first driver and the third driver can be implemented by the first driver, the first multiplexing circuit, the first comparator and the first calibration control circuit. After the calibration of the third driver, ZQ calibration of the second driver can be implemented by the second driver, the third driver, the second multiplexing circuit, the second comparator and the second calibration control circuit. This can achieve ZQ calibration of the pull-down driver and the pull-up driver, and also improve the accuracy of ZQ calibration.

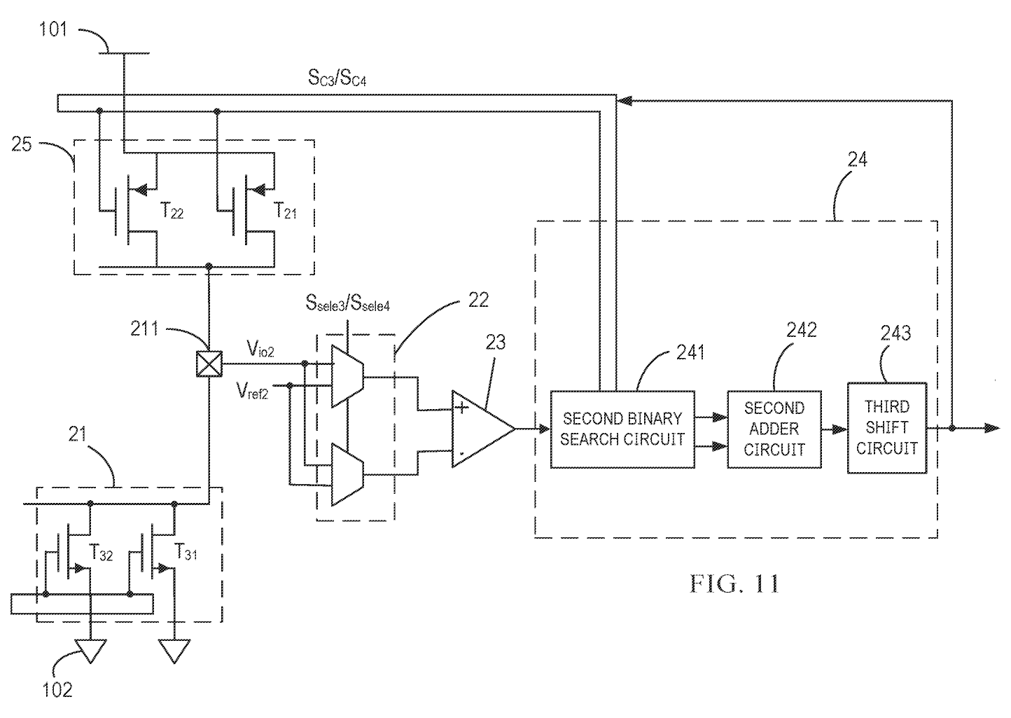

FIG. 11 is a circuit connection view schematically showing a calibration circuit according to other implementations of the present disclosure.

As shown in FIG. 11, the calibration circuit comprises the second driver 25, the third driver 21, the second multiplexing circuit 22, the second comparator 23 and the second calibration control circuit 24.

As shown in FIG. 11, the second driver 25 comprises one or more transistors. For example, as shown in FIG. 11, the second driver 25 comprises a seventh transistor T₂₁, an eighth transistor T₂₂ arranged in parallel with the seventh transistor T₂₁, and the like. A first terminal of the seventh transistor T₂₁ is connected to the second connection point 211. A second terminal of the seventh transistor T₂₁ is connected to the first voltage terminal 101. A control terminal of the seventh transistor T₂₁ is connected to the second calibration control circuit 24. A first terminal of the eighth transistor T₂₂ is connected to the second connection point 211. A second terminal of the eighth transistor T₂₂ is connected to the first voltage terminal 101. A control terminal of the eighth transistor T₂₂ is connected to the second calibration control circuit 24.

The third driver 21 comprises one or more transistors. For example, as shown in FIG. 11, the third driver 21 comprises a ninth transistor T₃₁, a tenth transistor T₃₂ arranged in parallel with the ninth transistor T₃₁, and the like. A first terminal of the ninth transistor T₃₁ is connected to the second connection point 211. A second terminal of the ninth transistor T₃₁ is connected to the second voltage terminal 102. A control terminal of the ninth transistor T₃₁ is connected to the first calibration control circuit 14 (not shown in FIG. 11). A first terminal of the tenth transistor T₃₂ is connected to the second connection point 211. A second terminal of the tenth transistor T₃₂is connected to the second voltage terminal 102. A control terminal of the tenth transistor T₃₂ is connected to the first calibration control circuit 14.

The second multiplexing circuit 22 comprises two multiplexers. The second multiplexing circuit 22 may have the same or similar structure as the multiplexing circuit 12 shown in FIG. 4, which will not be described in detail here. For example, the second multiplexing circuit 22 may use the structure of the multiplexing circuit as shown in FIG. 5.

As shown in FIG. 11, the second calibration control circuit 24 comprises: a second binary search circuit 241, a second adder circuit 242 and a third shift circuit 243.

An input terminal of the second binary search circuit 241 is connected to an output terminal of the second comparator 23. A first output terminal of the second binary search circuit 241 is connected to the control terminal of the second driver 25. The second binary search circuit 241 is configured to, by way of binary search, cyclically output a third resistance code based on a third comparison result to adjust a resistance value of the second driver until the third loop exit condition is met, and to, by way of binary search, cyclically output a fourth resistance code based on the fourth comparison result to adjust the resistance value of the second driver until a fourth loop exit condition is met.

For example, the third loop exit condition comprises a third predetermined number of cycle periods, and the fourth loop exit condition comprises a fourth predetermined number of cycle periods.

For example, the third loop exit condition is the same as the fourth loop exit condition. At this time, the third predetermined number is equal to the fourth predetermined number. In this way, it is beneficial to improve the accuracy of calibration.

Of course, those skilled in the art can understand that the third loop exit condition may also be different from the fourth loop exit condition.

For another example, the first loop exit condition, the second loop exit condition, the third loop exit condition and the fourth loop exit condition are all the same. In this way, it is beneficial to improve the accuracy of calibration.

As shown in FIG. 11, a first input terminal of the second adder circuit 242 is connected to a second output terminal of the second binary search circuit 241, and a second input terminal of the second adder circuit 242 is connected to a third output terminal of the second binary search circuit 241. The second adder circuit 242 is configured to perform an addition operation based on the third resistance code meeting the third loop exit condition and the fourth resistance code meeting the fourth loop exit condition to obtain a sum of the third resistance code and the fourth resistance code.

As shown in FIG. 11, an input terminal of the third shift circuit 243 is connected to an output terminal of the second adder circuit 242, and an output terminal of the third shift circuit 243 is connected to the control terminal of the second driver (not shown). The third shift circuit 243 is configured to shift the sum of the third resistance code and the fourth resistance code to the right (for example, to the right by one bit) to obtain an adjustment code. The adjustment code is half of the sum of the third resistance code and the fourth resistance code.

In this way, the second calibration control circuit is implemented by the second binary search circuit, the second adder circuit and the third shift circuit. The second calibration control circuit can implement the same or similar calibration control logic as the calibration control circuit in FIG. 4.

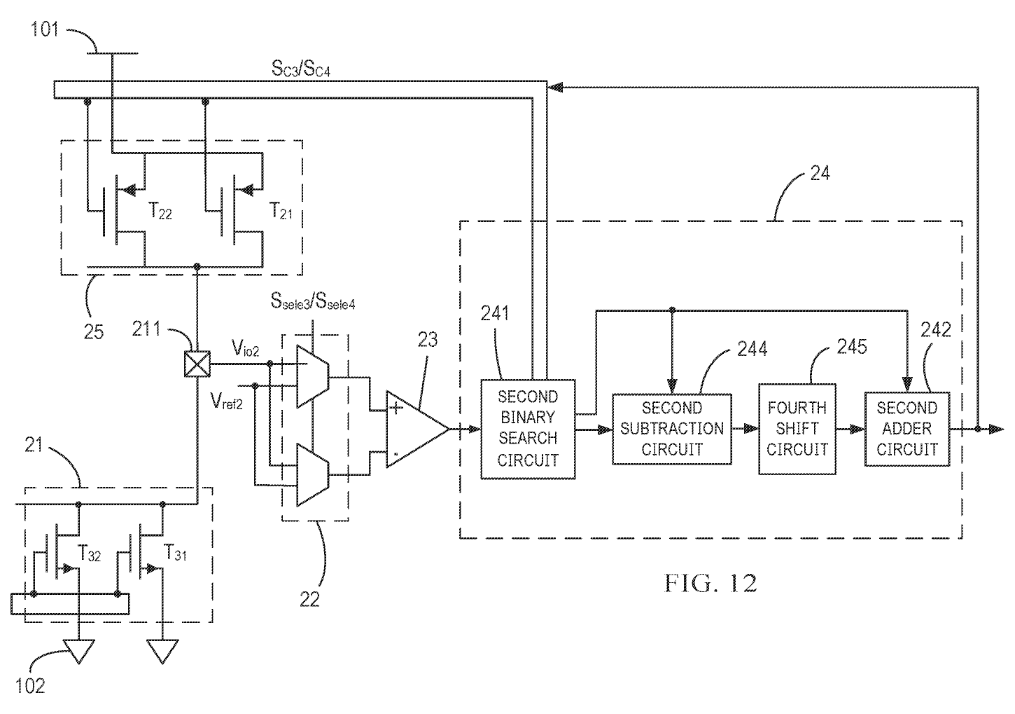

FIG. 12 is a circuit connection view schematically showing a calibration circuit according to other implementations of the present disclosure.

As shown in FIG. 12, the calibration circuit comprises the second driver 25, the third driver 21, the second multiplexing circuit 22, the second comparator 23 and the second calibration control circuit 24.

The second calibration control circuit 24 comprises a second binary search circuit 241. An input terminal of the second binary search circuit 241 is connected to an output terminal of the second comparator 23. A first output terminal of the second binary search circuit 241 is connected to the control terminal of the second driver. The second binary search circuit 241 is configured to, by way of binary search, cyclically output a third resistance code based on the third comparison result to adjust a resistance value of the second driver until a third loop exit condition is met, and to, by way of binary search, cyclically output a fourth resistance code based on the fourth comparison result to adjust the resistance value of the second driver until a fourth loop exit condition is met.

As shown in FIG. 12, the second calibration control circuit 24 further comprises a second subtraction circuit 244. A first input terminal of the second subtraction circuit 244 is connected to a second output terminal of the second binary search circuit 241. A second input terminal of the second subtraction circuit 244 is connected to a third output terminal of the second binary search circuit 241. The second subtraction circuit 244 is configured to perform a subtraction operation based on the third resistance code meeting the third loop exit condition and the fourth resistance code meeting the fourth loop exit condition to obtain a difference between the third resistance code and the fourth resistance code. Here, the second binary search circuit 241 outputs the third resistance code meeting the third loop exit condition through its second output terminal, and outputs the fourth resistance code meeting the fourth loop exit condition through its third output terminal.

As shown in FIG. 12, the second calibration control circuit 24 further comprises a fourth shift circuit 245. An input terminal of the fourth shift circuit 245 is connected to an output terminal of the second subtraction circuit 244. The fourth shift circuit 245 is configured to shift the difference between the third resistance code and the fourth resistance code to the right (for example, to the right by one bit) to obtain an offset code (which can be referred to as a second offset code). The offset code is half of the difference between the third resistance code meeting the third loop exit condition and the fourth resistance code meeting the fourth loop exit condition.

As shown in FIG. 12, the second calibration control circuit 24 further comprises a second adder circuit 242. A first input terminal of the second adder circuit 242 is connected to an output terminal of the fourth shift circuit 245. A second input terminal of the second adder circuit 242 is connected to the third output terminal of the second binary search circuit 241. The second adder circuit 242 is configured to perform an addition operation based on the offset code and the fourth resistance code meeting the fourth loop exit condition to obtain an adjustment code (which can be referred to as a second adjustment code). The adjustment code is used to perform ZQ calibration on the second driver. As described previously, the adjustment code is half of the sum of the third resistance code and the fourth resistance code.

In this way, the second calibration control circuit is implemented by the second binary search circuit, the second subtraction circuit, the fourth shift circuit and the second adder circuit. The second calibration control circuit can implement the same or similar calibration control logic as the calibration control circuit in FIG. 6.

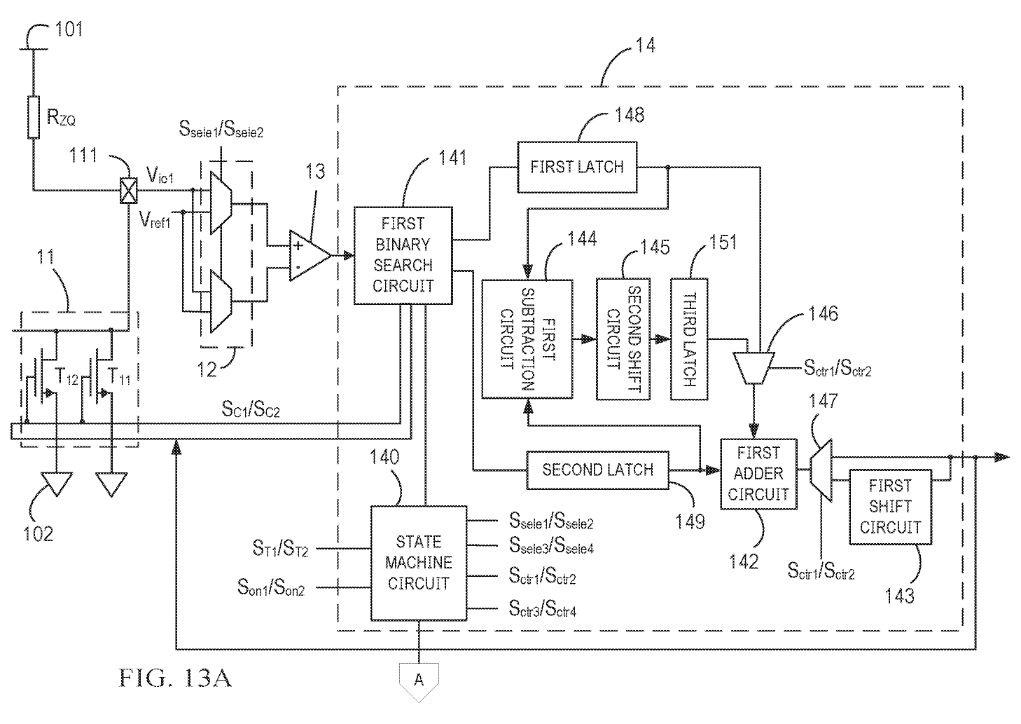

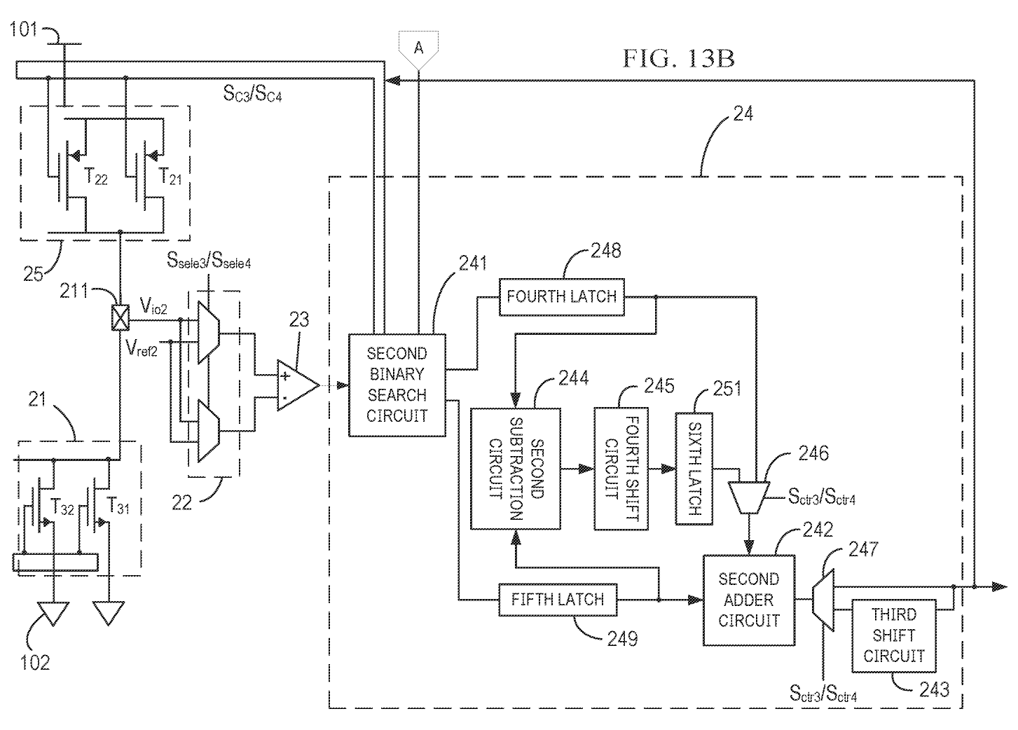

FIG. 13 is a circuit connection view schematically showing a calibration circuit according to other implementations of the present disclosure.

As shown in FIG. 13, the calibration circuit comprises a first driver 11, a first multiplexing circuit 12, a first comparator 13 and a first calibration control circuit 14. The first calibration control circuit 14 comprises a first binary search circuit 141, a first adder circuit 142, a first shift circuit 143, a first subtraction circuit 144, a second shift circuit 145, a third multiplexer 146, a fourth multiplexer 147, a first latch 148, a second latch 149, a third latch 151 and a state machine circuit 140. These circuits and devices are the same as or similar to corresponding circuits and devices in FIG. 7, which will not be described in detail here. An offset code involved during the operation process of these circuits and devices is referred to as the first offset code, and an adjustment code is referred to as the first adjustment code.

As shown in FIG. 13, the calibration circuit further comprises a second driver 25, a third driver 21, a second multiplexing circuit 22, a second comparator 23 and a second calibration control circuit 24.

As shown in FIG. 13, the second calibration control circuit 24 comprises a second binary search circuit 241. An input terminal of the second binary search circuit 241 is connected to an output terminal of the second comparator 23. A first output terminal of the second binary search circuit 241 is connected to a control terminal of the second driver 25.

As shown in FIG. 13, the second calibration control circuit 24 further comprises a second adder circuit 242. A first input terminal of the second adder circuit 242 is connected to a second output terminal of the second binary search circuit 241. A second input terminal of the second adder circuit 242 is connected to a third output terminal of the second binary search circuit 241.

As shown in FIG. 13, the second calibration control circuit 24 further comprises a third shift circuit 243. An input terminal of the third shift circuit 243 is connected to an output terminal of the second adder circuit 242. An output terminal of the third shift circuit 243 is connected to the control terminal of the second driver 25.

As shown in FIG. 13, the second calibration control circuit 24 further comprises a second subtraction circuit 244. A first input terminal of the second subtraction circuit 244 is connected to the second output terminal of the second binary search circuit 241. A second input terminal of the second subtraction circuit 244 is connected to the third output terminal of the second binary search circuit 241.

As shown in FIG. 13, the second calibration control circuit 24 further comprises a fourth shift circuit 245. An input terminal of the fourth shift circuit 245 is connected to an output terminal of the second subtraction circuit 244. An output terminal of the fourth shift circuit 245 is connected to the first input terminal of the second adder circuit 242.

As shown in FIG. 13, the second calibration control circuit 24 further comprises a fifth multiplexer 246. The fifth multiplexer 246 is arranged between the fourth shift circuit 245 and the second adder circuit 242, and between the second binary search circuit 241 and the second adder circuit 242. A first input terminal of the fifth multiplexer 246 is connected to the second output terminal of the second binary search circuit 241. A second input terminal of the fifth multiplexer 246 is connected to the output terminal of the fourth shift circuit 245. An output terminal of the fifth multiplexer 246 is connected to the first input terminal of the second adder circuit 242. A control terminal of the fifth multiplexer 246 is configured to receive the third control signal S_{ctr3} or the fourth control signal S_{ctr4}.

The fifth multiplexer 246 is configured to transmit the third resistance code to the second adder circuit in response to the third control signal, and transmit the offset code (e.g., the second offset code) to the second adder circuit in response to the fourth control signal. Therefore, the fifth multiplexer can transmit different codes to the second adder circuit through different control signals, so that the second adder circuit performs different addition operations.

As shown in FIG. 13, the second calibration control circuit 24 further comprises a sixth multiplexer 247. The sixth multiplexer 247 is arranged between the second adder circuit 242 and the third shift circuit 243. An input terminal of the sixth multiplexer 247 is connected to the output terminal of the second adder circuit 242. A first output terminal of the sixth multiplexer 247 is connected to a control terminal (not shown) of the second driver. A second output terminal of the sixth multiplexer 247 is connected to the input terminal of the third shift circuit 243. A control terminal of the sixth multiplexer 247 is configured to receive the third control signal S_{ctr3} or the fourth control signal S_{ctr4}.

The sixth multiplexer 247 is configured to transmit the sum of the third resistance code and the fourth resistance code output by the second adder circuit to the third shift circuit in response to the third control signal, and output the second adjustment code in response to the fourth control signal. This facilitates ZQ calibration of the second driver.

In some implementations, the state machine circuit 140 is configured to, based on a first on command Sₒₙ₁, output the first selection signal Sₛₑₗₑ₁ or the second selection signal Sₛₑₗₑ₂ and output the first control signal S_{ctr1} or the second control signal S_{ctr2}, and further configured to, based on a second on command Sₒₙ₂, output the third selection signal Sₛₑₗₑ₃ or the fourth selection signal Sₛₑₗₑ₄ and output the third control signal S_{ctr3} or the fourth control signal S_{ctr4}. In this way, the control of the first multiplexing circuit 12, the third multiplexer 146, the fourth multiplexer 147, the second multiplexing circuit 22, the fifth multiplexer 246 and the sixth multiplexer 247 is implemented, thereby achieving the control of ZQ calibration.

In some implementations, the state machine circuit 140 is further configured to, based on a first on command Sₒₙ₁ and a first temperature change signal S_{T1}, output the first selection signal Sₛₑₗₑ₁ or the second selection signal Sₛₑₗₑ₂ and output the first control signal S_{ctr1} or the second control signal S_{ctr2}, and further configured to, based on a second on command Sₒₙ₂ and a second temperature change signal S_{T2}, output the third selection signal Sₛₑₗₑ₃ or the fourth selection signal Sₛₑₗₑ₄ and output the third control signal S_{ctr3} or the fourth control signal S_{ctr4}. By incorporating the temperature change signal as a starting factor of starting ZQ calibration, it is possible to use different calibration control logics based on different temperature changes.

For example, the state machine circuit 140 is configured to output the first control signal in response to the first temperature change signal indicating that a change amplitude of a temperature of a memory within a predetermined time is greater than or equal to an amplitude threshold, and output the second control signal in response to the first temperature change signal indicating that the change amplitude of the temperature of the memory within the predetermined time is less than the amplitude threshold; and further configured to output the third control signal in response to the second temperature change signal indicating that the change amplitude of the temperature of the memory within the predetermined time is greater than or equal to the amplitude threshold, and output the fourth control signal in response to the second temperature change signal indicating that the change amplitude of the temperature of the memory within the predetermined time is less than the amplitude threshold.

In some implementations, as shown in FIG. 13, the second calibration control circuit 24 further comprises a fourth latch 248. The fourth latch 248 is arranged between the second binary search circuit 241 and the fifth multiplexer 246, and between the second binary search circuit 241 and the second subtraction circuit 244. An input terminal of the fourth latch 248 is connected to the second output terminal of the second binary search circuit 241. An output terminal of the fourth latch 248 is connected to the first input terminal of the fifth multiplexer 246 and the first input terminal of the second subtraction circuit 244. The fourth latch 248 is configured to latch the third resistance code meeting the third loop exit condition. This facilitates subsequent use of the third resistance code.

In some implementations, as shown in FIG. 13, the second calibration control circuit 24 further comprises a fifth latch 249. The fifth latch 249 is arranged between the second binary search circuit 241 and the second adder circuit 242, and between the second binary search circuit 241 and the second subtraction circuit 244. An input terminal of the fifth latch 249 is connected to the third output terminal of the second binary search circuit 241. An output terminal of the fifth latch 249 is connected to the second input terminal of the second adder circuit 242 and the second input terminal of the second subtraction circuit 244. The fifth latch 249 is configured to latch the fourth resistance code meeting the fourth loop exit condition. This facilitates subsequent use of the fourth resistance code.

In some implementations, as shown in FIG. 13, the calibration control circuit further comprises a sixth latch 251. The sixth latch 251 is arranged between the fourth shift circuit 245 and the fifth multiplexer 246. An input terminal of the sixth latch 251 is connected to the output terminal of the fourth shift circuit 245. An output terminal of the sixth latch 251 is connected to the second input terminal of the fifth multiplexer 246. The sixth latch 251 is configured to latch the second offset code. This facilitates subsequent use of the second offset code. For example, in a case where the change amplitude of the temperature of the memory within the predetermined time is less than the amplitude threshold, the ZQ calibration can be performed again by using the second offset code that has been obtained previously and the fourth resistance code meeting the fourth loop exit condition that is reobtained.

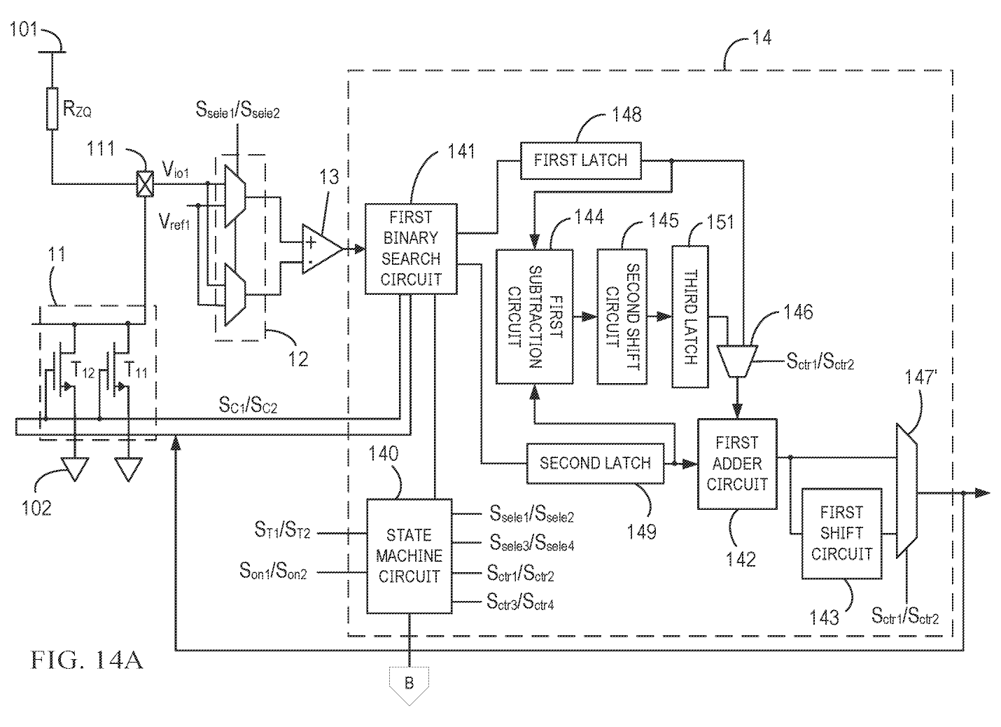

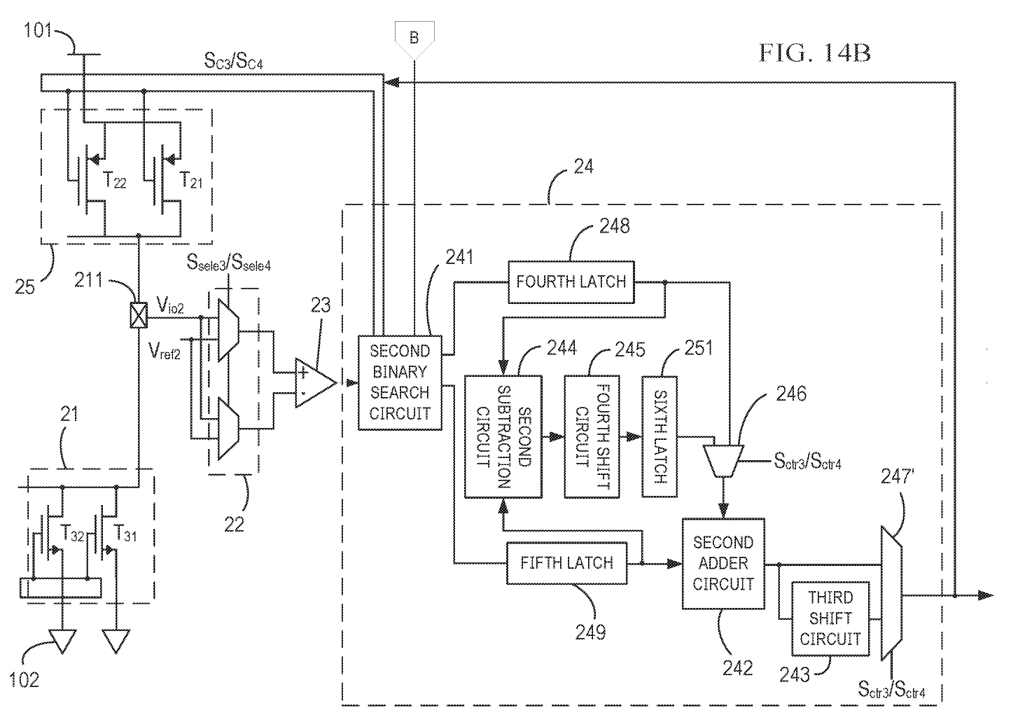

FIG. 14 is a circuit connection view schematically showing a calibration circuit according to other implementations of the present disclosure.

Compared with the calibration control circuit shown in FIG. 13, the calibration control circuit shown in FIG. 14 comprises a sixth multiplexer 247', wherein a connection circuit of the sixth multiplexer 247' is different from a connection circuit of the sixth multiplexer 247 in FIG. 13. As shown in FIG. 14, a first input terminal of the sixth multiplexer 247' is connected to the output terminal of the second adder circuit 242. A second input terminal of the sixth multiplexer 247' is connected to the output terminal of the third shift circuit 243. An input terminal of the third shift circuit 243 is connected to the output terminal of the second adder circuit 242. An output terminal of the sixth multiplexer 247' is connected to the control terminal of the second driver (not shown). A control terminal of the sixth multiplexer 247' is configured to receive the third control signal S_{ctr3} or the fourth control signal S_{ctr4}.

The sixth multiplexer 247' is configured to output the second adjustment code output by the third shift circuit 243 in response to the third control signal, and output the second adjustment code output by the second adder circuit 242 in response to the fourth control signal. In this way, the sixth multiplexer 247' outputs the second adjustment code for calibrating the second driver, thereby achieving ZQ calibration of the second driver.

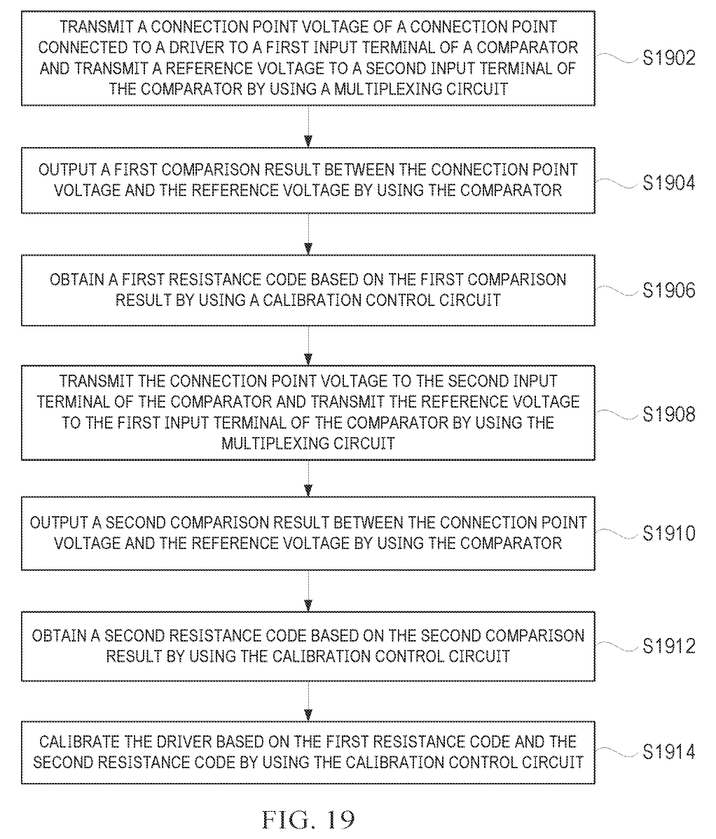

FIG. 19 is a flowchart showing a calibration method according to some implementations of the present disclosure. As shown in FIG. 19, the calibration method comprises steps S1902 to S1914.

In step S1902, by using a multiplexing circuit, a connection point voltage of a connection point connected is transmitted to a driver to a first input terminal of a comparator and a reference voltage is transmitted to a second input terminal of the comparator.

In step S1904, a first comparison result between the connection point voltage and the reference voltage is output by using the comparator.

In step S1906, a first resistance code is obtained based on the first comparison result by using a calibration control circuit.

In some implementations, the step S1906 comprises: cyclically outputting the first resistance code based on the first comparison result to adjust a resistance value of the driver until a first loop exit condition is met to obtain the first resistance code meeting the first loop exit condition.

For example, the cyclically outputting of the first resistance code based on the first comparison result comprises: by way of binary search, cyclically outputting the first resistance code based on the first comparison result to adjust the resistance value of the driver.

For example, the first loop exit condition comprises a first predetermined number of cycle periods.

In step S1908, the connection point voltage is transmitted to the second input terminal of the comparator and the reference voltage is transmitted to the first input terminal of the comparator by using the multiplexing circuit.

In step S1910, a second comparison result between the connection point voltage and the reference voltage is output by using the comparator.

In step S1912, a second resistance code is obtained based on the second comparison result by using the calibration control circuit.

In some implementations, the Step S1912 comprises: cyclically outputting the second resistance code based on the second comparison result to adjust the resistance value of the driver until a second loop exit condition is met to obtain the second resistance code meeting the second loop exit condition.

For example, the cyclically outputting of the second resistance code based on the second comparison result comprises: by way of binary search, cyclically outputting the second resistance code based on the second comparison result to adjust the resistance value of the driver.

For example, the second loop exit condition comprises a second predetermined number of cycle periods.

For example, the first loop exit condition is the same as the second loop exit condition. For example, the above-described first predetermined number is equal to the above-described second predetermined number.

In step S1914, the driver is calibrated based on the first resistance code and the second resistance code by using the calibration control circuit.

In some implementations, the step S1914 comprises: calibrating the driver based on the first resistance code meeting the first loop exit condition and the second resistance code meeting the second loop exit condition.

For example, the step S1914 comprises: calculating an adjustment code based on the first resistance code and the second resistance code, wherein the adjustment code is half of a sum of the first resistance code and the second resistance code; and calibrating the driver based on the adjustment code.

For another example, the step S1914 comprises: calculating an offset code based on the first resistance code and the second resistance code, wherein the offset code is half of a difference between the first resistance code and the second resistance code; calculating an adjustment code based on the first resistance code or the second resistance code and based on the offset code; and calibrating the driver based on the adjustment code.

So far, a calibration method according to some implementations of the present disclosure has been provided. The calibration method comprises: transmitting a connection point voltage of a connection point connected to a driver to a first input terminal of a comparator and transmitting a reference voltage to a second input terminal of the comparator by using a multiplexing circuit; outputting a first comparison result between the connection point voltage and the reference voltage by using the comparator; obtaining a first resistance code based on the first comparison result by using a calibration control circuit; transmitting the connection point voltage to the second input terminal of the comparator and transmitting the reference voltage to the first input terminal of the comparator by using the multiplexing circuit; outputting a second comparison result between the connection point voltage and the reference voltage by using the comparator; obtaining a second resistance code based on the second comparison result by using the calibration control circuit; and calibrating the driver based on the first resistance code and the second resistance code by using the calibration control circuit. In the calibration method, the connection point voltage and the reference voltage are transmitted to the comparator through the multiplexing circuit in two different states so that the comparator obtains two comparison results, and further the calibration control circuit calibrates the driver, which can improve the accuracy of ZQ calibration. The calibration method is more flexible and reduces the cost.

In some implementations, the calibration method further comprises: reobtaining the first resistance code and the second resistance code in response to a change amplitude of a temperature of a memory within a predetermined time being greater than or equal to an amplitude threshold; calculating the adjustment code based on the first resistance code and the second resistance code which are reobtained, wherein the adjustment code is half of a sum of the first resistance code and the second resistance code; and recalibrating the driver based on the adjustment code. This achieves the recalibration of the driver and improves the accuracy of ZQ calibration in the case where the change amplitude of the temperature of the memory within the predetermined time is relatively great.

In some implementations, the calibration method further comprises: reobtaining the first resistance code or the second resistance code in response to a change amplitude of a temperature of a memory within a predetermined time being less than an amplitude threshold; calculating the adjustment code based on the first resistance code or the second resistance code which is reobtained and based on the offset code; and recalibrating the driver based on the adjustment code. This achieves the recalibration of the driver, improves the accuracy of ZQ calibration, and saves the time cost in the case where the change amplitude of the temperature of the memory within the predetermined time is relatively slight.

It is to be noted that, the above-described calibration method can be applied to a calibration circuit comprising the first driver 11, the first multiplexing circuit 12, the first comparator 13 and the first calibration control circuit 14, and also applied to a calibration circuit comprising the second driver 25, the third driver 21, the second multiplexing circuit 22, the second comparator 23 and the second calibration control circuit 24. The calibration method can be used to perform ZQ calibration on the first driver, and perform ZQ calibration on the third driver which is the same as the first driver. After ZQ calibration is performed on the third driver, the calibration method can be then used to calibrate the second driver. In this way, ZQ calibration of different drivers is achieved, and the accuracy of ZQ calibration is also improved.

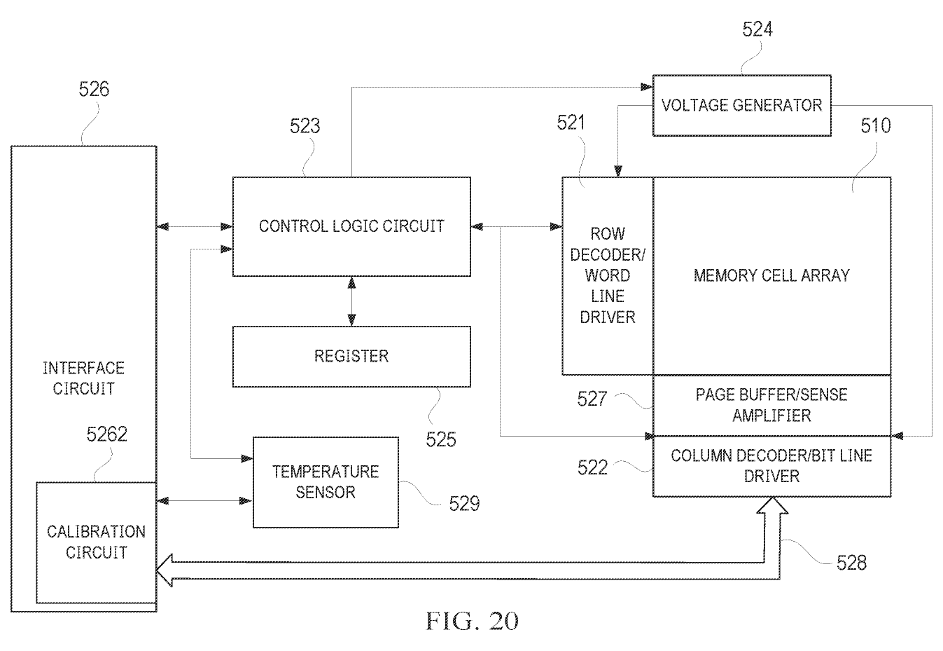

FIG. 20 is a schematic structural view showing a memory according to some implementations of the present disclosure. For example, the memory is DRAM, NAND, or the like.

As shown in FIG. 20, the memory comprises a memory cell array 510 and a peripheral circuit. The peripheral circuit comprises a word line driver 521 coupled to the memory cell array 510. The peripheral circuit further comprises a page buffer 527 coupled to the memory cell array 510. The peripheral circuit further comprises a control logic circuit 523 coupled to the word line driver 521 and the page buffer 527. The peripheral circuit further comprises an interface circuit 526 coupled to the control logic circuit 523. The interface circuit 526 comprises a calibration circuit 5262. For example, the calibration circuit 5262 is the calibration circuit described previously.

For example, FIG. 20 shows some exemplary peripheral circuits comprising a page buffer/sense amplifier 527, a column decoder/bit line driver 522, a row decoder/word line driver 521, a voltage generator 524, a control logic circuit 523, a register 525, an interface circuit 526 and a data bus 528. The register 525 is coupled to the control logic circuit 523. It should be understood that, additional peripheral circuits not shown in FIG. 20 may also be comprised.

The page buffer/sense amplifier 527 is configured to read and program (write) data from the memory cell array according to a control signal from the control logic circuit 523. In an example, the page buffer/sense amplifier 527 may store one page of programming data (written data) to be programmed into one page of the memory cell array 510. In another example, the page buffer/sense amplifier 527 may perform a program verification operation to ensure that data has been correctly programmed into the coupled memory cells. In a further example, the page buffer/sense amplifier 527 may also sense a low power signal indicating a data bit stored in a memory cell from a bit line in a reading operation, and amplify a small voltage swing to a recognizable logic level. The column decoder/bit line driver 522 is configured to be controlled by the control logic circuit 523 and select one or more memory strings by applying a bit line voltage generated by the voltage generator 524.

The row decoder/word line driver 521 is configured to be controlled by the control logic circuit 523, and select/deselect blocks of the memory cell array 510 and select/deselect word lines of the blocks. The row decoder/word line driver 521 may further be configured to drive word lines (not shown) using the word line voltage generated by the voltage generator 524. The row decoder/word line driver 521 is configured to apply a read voltage to a selected word line in a reading operation of a memory cell coupled to the selected word line.

The voltage generator 524 is coupled to the control logic circuit 523, the word line driver 521, the bit line driver 522 and the page buffer 527. The voltage generator 524 is configured to be controlled by the control logic circuit 523 and generate a word line voltage (for example, a read voltage, a program voltage, a pass voltage, a local voltage, a verify voltage, or the like), a bit line voltage, and a source line voltage to be provided to the memory cell array.

The control logic circuit 523 is coupled to each peripheral circuit and configured to control the operation of each peripheral circuit. The register 525 is coupled to the control logic circuit 523, and comprises a status register, a command register and an address register for storing status information, a command operation code and a command address for controlling the operation of each peripheral circuit.

The interface circuit 526 is coupled to the control logic circuit 523 and function as a control buffer to buffer a control command received from a controller (not shown) and forward the control command to the control logic circuit 523, and buffer the status information received from the control logic circuit 523 and forward the status information to the controller. The interface circuit 526 is also coupled to the column decoder/bit line driver 522 via the data bus 528 and serve as a data input/output interface and a data buffer, thereby buffering and forwarding data to and from the memory cell array.

As shown in FIG. 20, the peripheral circuit further comprises a temperature sensor 529. The temperature sensor is configured to collect the temperature information and transmit the temperature information to the calibration circuit 5262. The temperature sensor 529 is connected to the control logic circuit 523.

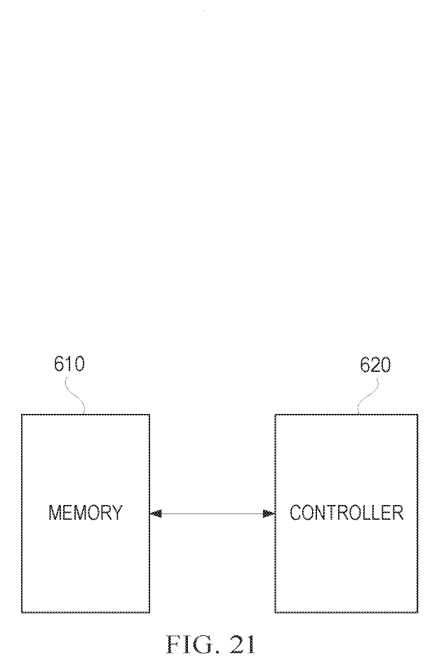

FIG. 21 is a schematic structural view showing a system according to some implementations of the present disclosure.

For example, the system is a mobile phone, a desktop computer, a laptop computer, a tablet computer, a vehicle-mounted computer, a game console, a printer, a positioning device, a wearable electronic device, a smart sensor, a virtual reality device, an augmented reality device, or any other suitable electronic device having a memory therein.

As shown in FIG. 21, the system comprises a memory 610 and a controller 620. For example, the memory 610 is the memory shown in FIG. 20. The controller 620 is coupled to the memory 610. The controller 620 may be a processor of an electronic device, for example, a central processing unit, or a system on chip, for example, an application processor. The controller 620 is configured to transmit data to the memory 610 or receive data from the memory 610.

Hereto, various implementations of the present disclosure have been described in detail. Some details well known in the art are not described in order to avoid obscuring the concept of the present disclosure. According to the above description, those skilled in the art would fully understand how to implement the technical solutions disclosed here.

Although some specific implementations of the present disclosure have been described in detail by way of examples, those skilled in the art should understand that the above examples are turned only for an illustrative purpose, rather than limiting the scope of the present disclosure. It should be understood by those skilled in the art that modifications to the above implementations and equivalent replacements to some technical features may be made without departing from the scope and spirit of the present disclosure. The scope of the present disclosure is defined by the appended claims.

What is claimed is:

1. A calibration circuit, comprising:
a driver coupled to a connection point;
a multiplexing circuit, wherein a first input terminal of the multiplexing circuit is coupled to the connection point, a second input terminal of the multiplexing circuit is configured to receive a reference voltage, and the multiplexing circuit is configured to:
in response to a first selection signal, output a connection point voltage of the connection point through a first output terminal of the multiplexing circuit and output the reference voltage through a second output terminal of the multiplexing circuit; and
in response to a second selection signal, output the connection point voltage through the second output terminal of the multiplexing circuit and output the reference voltage through the first output terminal of the multiplexing circuit;
a comparator, wherein a first input terminal of the comparator is coupled to the first output terminal of the multiplexing circuit, and a second input terminal of the comparator is coupled to the second output terminal of the multiplexing circuit; and
a calibration control circuit, wherein an input terminal of the calibration control circuit is coupled to an output terminal of the comparator, an output terminal of the calibration control circuit is coupled to a control terminal of the driver, and the calibration control circuit is configured to calibrate the driver.

2. The calibration circuit of claim 1, wherein the multiplexing circuit comprises:
a first multiplexer, wherein a first input terminal of the first multiplexer is coupled to the connection point, a second input terminal of the first multiplexer is configured to receive the reference voltage, an output terminal of the first multiplexer is coupled to the first input terminal of the comparator, and a control terminal of the first multiplexer is configured to receive the first selection signal or the second selection signal; and
a second multiplexer, wherein a first input terminal of the second multiplexer is coupled to the connection point, a second input terminal of the second multiplexer is configured to receive the reference voltage, an output terminal of the second multiplexer is coupled to the second input terminal of the comparator, and a control terminal of the second multiplexer is configured to receive the first selection signal or the second selection signal.

3. The calibration circuit of claim 2, wherein the first multiplexer comprises:
a first transistor, wherein a first terminal of the first transistor is configured to receive the connection point voltage, a second terminal of the first transistor serves as the output terminal of the first multiplexer, and a control terminal of the first transistor is configured to receive the first selection signal or the second selection signal; and
a second transistor, wherein a first terminal of the second transistor is configured to receive the reference voltage, a second terminal of the second transistor is coupled to the second terminal of the first transistor, and a control terminal of the second transistor is coupled to the control terminal of the first transistor, wherein a conductivity type of the second transistor is opposite to a conductivity type of the first transistor.

4. The calibration circuit of claim 3, wherein the second multiplexer comprises:
a third transistor, wherein a first terminal of the third transistor is coupled to the first terminal of the first transistor, a second terminal of the third transistor serves as the output terminal of the second multiplexer, and a control terminal of the third transistor is coupled to the control terminal of the first transistor, wherein a conductivity type of the third transistor is opposite to the conductivity type of the first transistor; and
a fourth transistor, wherein a first terminal of the fourth transistor is coupled to the first terminal of the second transistor, a second terminal of the fourth transistor is coupled to the second terminal of the third transistor, and a control terminal of the fourth transistor is coupled to the control terminal of the first transistor, wherein a conductivity type of the fourth transistor is the same as the conductivity type of the first transistor.

5. The calibration circuit of claim 1, wherein the connection point is configured to be coupled to an external resistor.

6. The calibration circuit of claim 1, wherein the calibration control circuit comprises:
a binary search circuit, wherein an input terminal of the binary search circuit is coupled to the output terminal of the comparator, and a first output terminal of the binary search circuit is coupled to the control terminal of the driver;
an adder circuit, wherein a first input terminal of the adder circuit is coupled to a second output terminal of the binary search circuit, and a second input terminal of the adder circuit is coupled to a third output terminal of the binary search circuit; and
a first shift circuit, wherein an input terminal of the first shift circuit is coupled to an output terminal of the adder circuit, and an output terminal of the first shift circuit is coupled to the control terminal of the driver.

7. The calibration circuit of claim 1, wherein the calibration control circuit comprises:
a binary search circuit, wherein an input terminal of the binary search circuit is coupled to the output terminal of the comparator, and a first output terminal of the binary search circuit is coupled to the control terminal of the driver;
a subtraction circuit, wherein a first input terminal of the subtraction circuit is coupled to a second output terminal of the binary search circuit, and a second input terminal of the subtraction circuit is coupled to a third output terminal of the binary search circuit;
a second shift circuit, wherein an input terminal of the second shift circuit is coupled to an output terminal of the subtraction circuit; and
an adder circuit, wherein a first input terminal of the adder circuit is coupled to an output terminal of the second shift circuit, and a second input terminal of the adder circuit is coupled to the third output terminal of the binary search circuit.

8. The calibration circuit of claim 6, wherein the calibration control circuit further comprises:
a subtraction circuit, wherein a first input terminal of the subtraction circuit is coupled to the second output terminal of the binary search circuit, and a second input terminal of the subtraction circuit is coupled to the third output terminal of the binary search circuit; and
a second shift circuit, wherein an input terminal of the second shift circuit is coupled to an output terminal of the subtraction circuit, and an output terminal of the second shift circuit is coupled to the first input terminal of the adder circuit.

9. The calibration circuit of claim 8, wherein the calibration control circuit further comprises:
a third multiplexer arranged between the second shift circuit and the adder circuit and between the binary search circuit and the adder circuit, wherein a first input terminal of the third multiplexer is coupled to the second output terminal of the binary search circuit, a second input terminal of the third multiplexer is coupled to the output terminal of the second shift circuit, an output terminal of the third multiplexer is coupled to the first input terminal of the adder circuit, and a control terminal of the third multiplexer is configured to receive a first control signal or a second control signal.

10. The calibration circuit of claim 9, wherein the calibration control circuit further comprises:
a fourth multiplexer arranged between the adder circuit and the first shift circuit, wherein an input terminal of the fourth multiplexer is coupled to the output terminal of the adder circuit, a first output terminal of the fourth multiplexer is coupled to the control terminal of the driver, a second output terminal of the fourth multiplexer is coupled to the input terminal of the first shift circuit, and a control terminal of the fourth multiplexer is configured to receive the first control signal or the second control signal.

11. The calibration circuit of claim 9, wherein the calibration control circuit further comprises:
a fourth multiplexer, wherein a first input terminal of the fourth multiplexer is coupled to the output terminal of the adder circuit, a second input terminal of the fourth multiplexer is coupled to the output terminal of the first shift circuit, an output terminal of the fourth multiplexer is coupled to the control terminal of the driver, and a control terminal of the fourth multiplexer is configured to receive the first control signal or the second control signal.

12. The calibration circuit of claim 10, wherein the calibration control circuit further comprises:
a state machine circuit, wherein a first input terminal of the state machine circuit is configured to receive an on command, a first output terminal of the state machine circuit is configured to output the first selection signal or the second selection signal, and a second output terminal of the state machine circuit is configured to output the first control signal or the second control signal.

13. The calibration circuit of claim 12, wherein a second input terminal of the state machine circuit is configured to receive a temperature change signal.

14. The calibration circuit of claim 9, wherein the calibration control circuit further comprises:
a first latch arranged between the binary search circuit and the third multiplexer and between the binary search circuit and the subtraction circuit, wherein an input terminal of the first latch is coupled to the second output terminal of the binary search circuit, and an output terminal of the first latch is coupled to the first input terminal of the third multiplexer and the first input terminal of the subtraction circuit; and
a second latch arranged between the binary search circuit and the adder circuit and between the binary search circuit and the subtraction circuit, wherein an input terminal of the second latch is coupled to the third output terminal of the binary search circuit, and an output terminal of the second latch is coupled to the second input terminal of the adder circuit and the second input terminal of the subtraction circuit.

15. The calibration circuit of claim 9, wherein the calibration control circuit further comprises:
a third latch arranged between the second shift circuit and the third multiplexer, wherein an input terminal of the third latch is coupled to the output terminal of the second shift circuit, and an output terminal of the third latch is coupled to the second input terminal of the third multiplexer.

16. The calibration circuit of claim 1, wherein the driver is a pull-down driver or a pull-up driver.

17. A memory, comprising:
a memory cell array; and
a peripheral circuit comprising:
a word line driver coupled to the memory cell array;
a page buffer coupled to the memory cell array;
a control logic circuit coupled to the word line driver and the page buffer; and
an interface circuit coupled to the control logic circuit, wherein the interface circuit comprises a calibration circuit that comprises:
a driver coupled to a connection point;
a multiplexing circuit, wherein a first input terminal of the multiplexing circuit is coupled to the connection point, a second input terminal of the multiplexing circuit is configured to receive a reference voltage, and the multiplexing circuit is configured to:
in response to a first selection signal, output a connection point voltage of the connection point through a first output terminal of the multiplexing circuit and output the reference voltage through a second output terminal of the multiplexing circuit; and
in response to a second selection signal, output the connection point voltage through the second output terminal of the multiplexing circuit and output the reference voltage through the first output terminal of the multiplexing circuit;
a comparator, wherein a first input terminal of the comparator is coupled to the first output terminal of the multiplexing circuit, and a second input terminal of the comparator is coupled to the second output terminal of the multiplexing circuit; and
a calibration control circuit, wherein an input terminal of the calibration control circuit is coupled to an output terminal of the comparator, an output terminal of the calibration control circuit is coupled to a control terminal of the driver, and the calibration control circuit is configured to calibrate the driver.

18. A calibration method, comprising:
transmitting a connection point voltage of a connection point coupled to a driver to a first input terminal of a comparator and transmitting a reference voltage to a second input terminal of the comparator by using a multiplexing circuit;
outputting a first comparison result between the connection point voltage and the reference voltage by using the comparator;
obtaining a first resistance code based on the first comparison result by using a calibration control circuit;
transmitting the connection point voltage to the second input terminal of the comparator and transmitting the reference voltage to the first input terminal of the comparator by using the multiplexing circuit;
outputting a second comparison result between the connection point voltage and the reference voltage by using the comparator;
obtaining a second resistance code based on the second comparison result by using the calibration control circuit; and
calibrating the driver based on the first resistance code and the second resistance code by using the calibration control circuit.

19. The calibration method of claim 18, wherein:
obtaining of the first resistance code based on the first comparison result by using the calibration control circuit comprises: cyclically outputting the first resistance code based on the first comparison result to adjust a resistance value of the driver until a first loop exit condition is met to obtain the first resistance code meeting the first loop exit condition;
obtaining of the second resistance code based on the second comparison result by using the calibration control circuit comprises: cyclically outputting the second resistance code based on the second comparison result to adjust the resistance value of the driver until a second loop exit condition is met to obtain the second resistance code meeting the second loop exit condition; and
calibrating of the driver based on the first resistance code and the second resistance code by using the calibration control circuit comprises: calibrating the driver based on the first resistance code meeting the first loop exit condition and the second resistance code meeting the second loop exit condition.

20. The calibration method of claim 18, wherein the calibrating of the driver based on the first resistance code and the second resistance code by using the calibration control circuit comprises:
calculating an adjustment code based on the first resistance code and the second resistance code, wherein the adjustment code is half of a sum of the first resistance code and the second resistance code; and
calibrating the driver based on the adjustment code.
